(19) United States
(12) Patent Application Publication
(10) Pub. No.: US 2025/0210768 A1
(43) Pub. Date: Jun. 26, 2025

(54) ACCOMMODATION DEVICE

(71) Applicant: HONDA MOTOR CO., LTD., Tokyo (JP)

(72) Inventors: Masashi Kai, Wako-shi, Saitama (JP); Kosuke Yamana, Wako-shi, Saitama (JP)

(21) Appl. No.: 18/850,606

(22) PCT Filed: Mar. 31, 2023
(86) PCT No.: PCT/JP2023/013523

§ 371 Date: Sep. 25, 2024

(30) Foreign Application Priority Data
Mar. 31, 2022 (JP) 2022-060156
Aug. 29, 2022 (JP) 2022-136282
Sep. 15, 2022 (JP) 2022-147335

(51) Int. Cl. H01M 50/202; H01M 10/42; H01M 10/44; H01M 10/48; H01M 50/256; H01M 50/271

(52) U.S. Cl. CPC H01M 50/202; H01M 10/425; H01M 10/44; H01M 10/488; H01M 50/256; H01M 50/271

(57) ABSTRACT

An accommodation device includes a housing including six substantially quadrangular surfaces facing mutually different directions, the housing being provided in a substantially polyhedral shape, and an accommodation unit provided inside the housing, the accommodation unit accommodating a portable energy accumulator. An opening is provided in the accommodation unit to enable the portable energy accumulator to be inserted and removed, the opening is provided at a position corresponding to a first surface being one of the six surfaces. The first surface includes a first side and a second side, which are parallel to one another. A, first handle is provided at the first side on the housing and a second handle is provided at the second side on the housing.

### TECHNICAL FIELD

The present invention relates to an accommodation device.

### BACKGROUND ART

Conventionally, an accommodation device is known, the accommodation device including an accommodation unit that insertably and removably accommodates an accommodated item (for example, refer to Patent Literature 1). This accommodation device includes a housing having six substantially quadrangular surfaces facing mutually different directions, the housing being formed in a substantially polyhedral shape, and this accommodation device includes an accommodation unit formed inside the housing. An opening linked to the accommodation unit or a circumferential edge portion of an opening linked to the accommodation unit is disposed, at a position corresponding to a first side, on this housing, the first side being one of a plurality of sides constituting a polyhedral corresponding to the housing. Moreover, a gripping portion is provided on this accommodation device, the gripping portion functioning as a handle capable of holding the accommodation device, by a user holding this handle.

### CITATION LIST

### Patent Literature

### Patent Literature 1

International Patent Publication No. WO 2020/235637

### SUMMARY OF INVENTION

### Technical Problem

However, in a conventional configuration, since an opening of the accommodation unit is disposed at one corner portion of the housing, the handle cannot be provided at this corner portion, and there is a fear of the portability being lowered. The present invention provides an accommodation device that can improve the portability.

### Solution to Problem

All of the content of Japanese Patent Application No. 2022-060156 filed on Mar. 31, 2022, Japanese Patent Application No. 2022-136282 filed on Aug. 29, 2022, and Japanese Patent Application No. 2022-147335 filed on Sep. 15, 2022 is included in this specification.

The present invention is an accommodation device that includes a housing comprising six substantially quadrangular surfaces facing mutually different directions, the housing being provided in a substantially polyhedral shape, and an accommodation unit provided inside the housing, the accommodation unit accommodating a portable energy accumulator to enable the portable energy accumulator to be inserted and removed, in which an opening is provided on the accommodation unit, the opening enabling the portable energy accumulator to be inserted and removed, the opening is provided at a position corresponding to a first surface being one of the six surfaces, the first surface has a first side and a second side, the first side and the second side being two sides parallel to one another, a first handle is provided at a position corresponding to the first side on the housing, the first handle being for a user to hold, and a second handle is provided at a position corresponding to the second side on the housing, the second handle being for the user to hold.

### Advantageous Effect of Invention

According to the present invention, the portability can be improved.

### BRIEF DESCRIPTION OF DRAWINGS

FIG. 1 is a perspective view of an accommodation device relating to an embodiment of the present invention.

FIG. 2 is an exploded perspective view of a housing.

FIG. 3 is a perspective view showing an upper portion of the accommodation device.

FIG. 4 is a horizontal cross-section view in which the accommodation device is cut at Plane IV shown in FIG. 1.

FIG. 5 is a figure in which the accommodation device is seen from a lower surface side.

FIG. 6 is an exploded perspective view of the accommodation device.

FIG. 7 is a longitudinal cross-section view in which the accommodation device is cut at Plane VII shown in FIG. 1.

FIG. 8 is a figure showing members stored in the accommodation device.

FIG. 9 is a schematic view in which an accommodation mechanism is seen from a right direction of the accommodation device.

FIG. 10 is a schematic view in which the accommodation mechanism is seen from a right direction of the accommodation device.

FIG. 11 is a side surface view in which the accommodation device is seen from the right side.

FIG. 12 is a schematic view showing a flow of cooling air in the accommodation device.

FIG. 13 is a schematic view showing a flow of cooling air in the accommodation device.

### DESCRIPTION OF EMBODIMENTS

### 1. Embodiment

### (1.1. Configuration)

Hereinafter, an embodiment of the present invention will be described by referring to the figures. In each of the figures, reference symbol FR shows the front in a state where an accommodation device 1 is installed (loaded) with a lower surface as a bottom surface in contact with an installation surface, reference symbol UP shows above the accommodation device 1, and reference symbol LH shows the left of the accommodation device 1. In the following description, as long as there is no particular description, each direction is a direction along these directions of the accommodation device 1. Hereinafter, a so-called upright posture is called a first posture, the so-called upright posture being a state where the accommodation device 1 is installed with a lower surface as a bottom surface in contact with an installation surface.

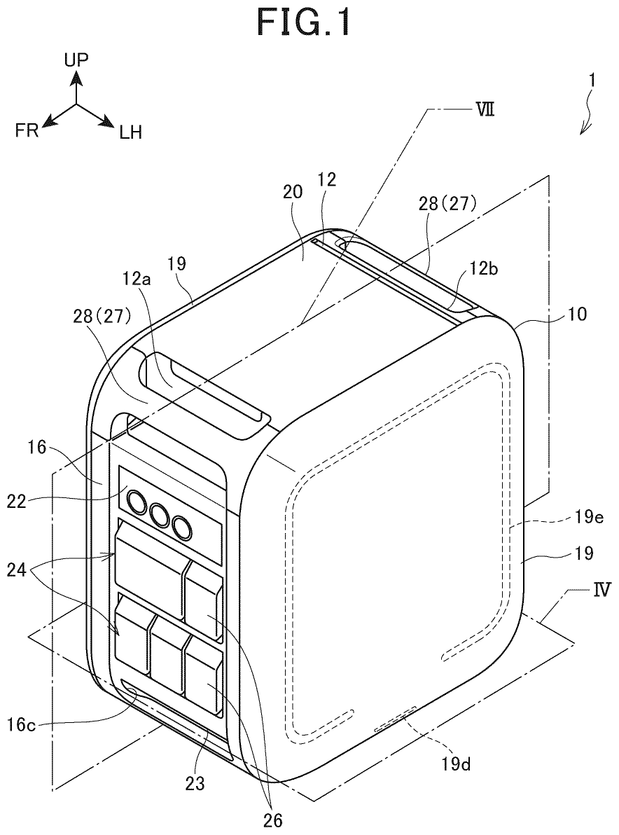

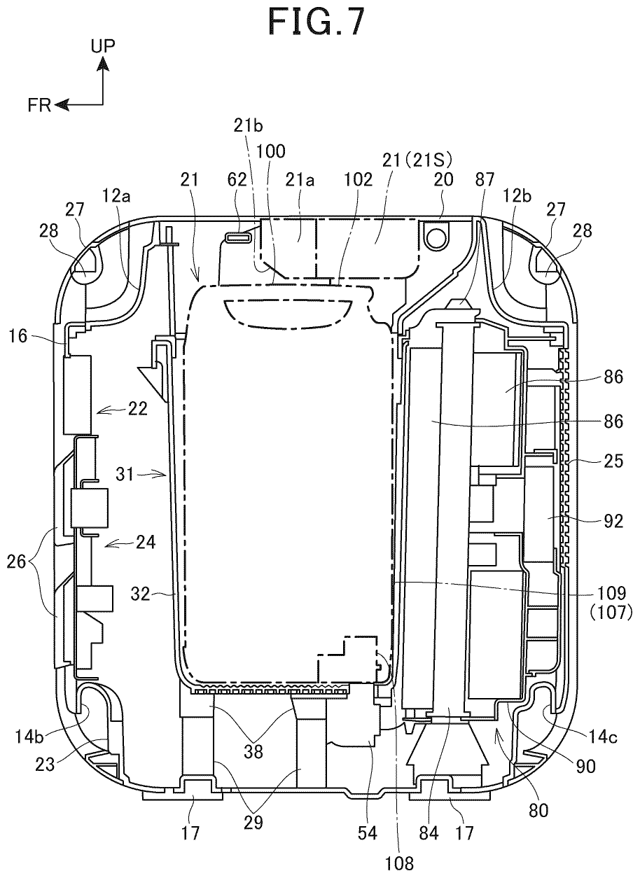

FIG. 1 is a perspective view of the accommodation device 1 relating to an embodiment of the present invention. The accommodation device 1 accommodates a battery 100 capable of being attached/detached to/from the accommodation device 1, the accommodation device 1 converts electrical power stored in the battery 100 in accordance with an operation of a user, and the accommodation device 1 functions as an electrical power supply device for supplying electrical power to an electric device or the like outside of the accommodation device 1 (FIG. 7). As shown in FIG. 1, the accommodation device 1 includes a substantially rectangular parallelepiped housing 10. The housing 10 includes an upper surface, a lower surface, a front surface, a rear surface, and a pair of side surfaces positioned on the left and right, the upper surface, the lower surface, the front surface, the rear surface, and the pair of side surfaces all being flat surfaces. In a first posture of the accommodation device 1, the lower surface of the housing 10 becomes the bottom surface in contact with the installation surface. Note that, the housing 10 is not limited to a rectangular parallelepiped shape, and the housing 10 may have any type of shape, for example, if the shape has six substantially quadrangular surfaces facing mutually different directions, and if the shape is substantially polyhedral, such as a substantially cubic shape.

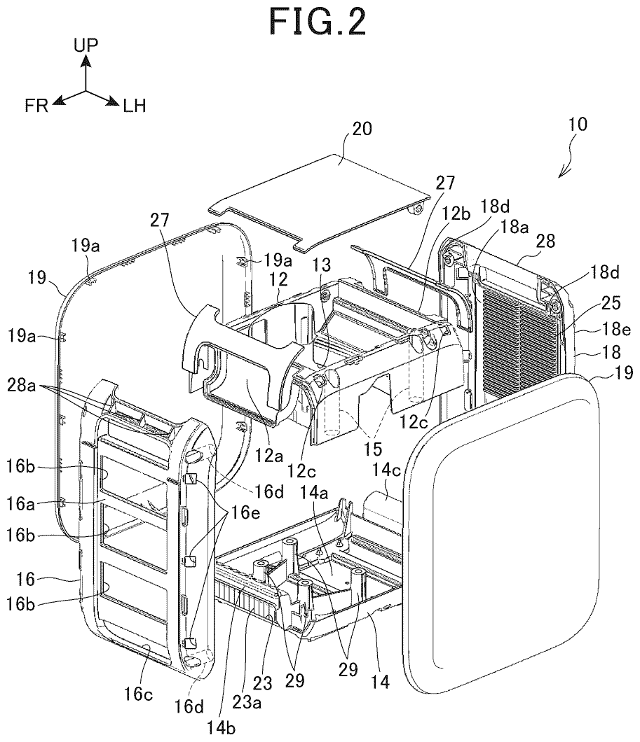

FIG. 2 is an exploded perspective view of the housing 10. In FIG. 2, the members stored inside the housing 10, such as an accommodation mechanism 30 and an inverter unit 80, are omitted. As shown in FIG. 2, the housing 10, in the first posture of the accommodation device 1, includes an upper surface panel 12 forming the upper surface, a lower surface panel 14 forming the lower surface, the lower surface becoming the bottom surface, a front surface panel 16 forming the front surface, a rear surface panel 18 forming the rear surface, and a pair of side surface panels 19 forming each of the left and right side surfaces. In the present embodiment, while each panel is formed by a resin material, the present invention is not limited to this, and a portion of at least one or any number of the panels may be formed by another material such as a metallic material.

The upper surface panel 12 is a member formed so as to include a predetermined thickness dimension, by forming the upper surface panel 12 so that each edge portion of a substantially rectangular plate shaped material is folded downward along an up-down direction of the accommodation device 1. An upper surface recessed portion 11 is provided on the upper surface panel 12, a substantial center of the upper surface recessed portion 11 being recessed in a rectangular shape in a planar view from an upper surface side toward a lower surface side. An upper surface opening 13 is provided at a substantial center of a bottom surface of the upper surface recessed portion 11, the upper surface opening 13 being a substantially rectangular shaped through hole in a planar view. Screw holes 15 are provided, at positions in the vicinity of each corner portion of the upper surface opening 13, on the bottom surface of the upper surface recessed portion 11, the screw holes 15 being through holes. Engagement holes 12c are provided, at positions adjacent to each of the screw holes 15, the engagement holes 12c being recessed portions with which a claw shaped member can engage.

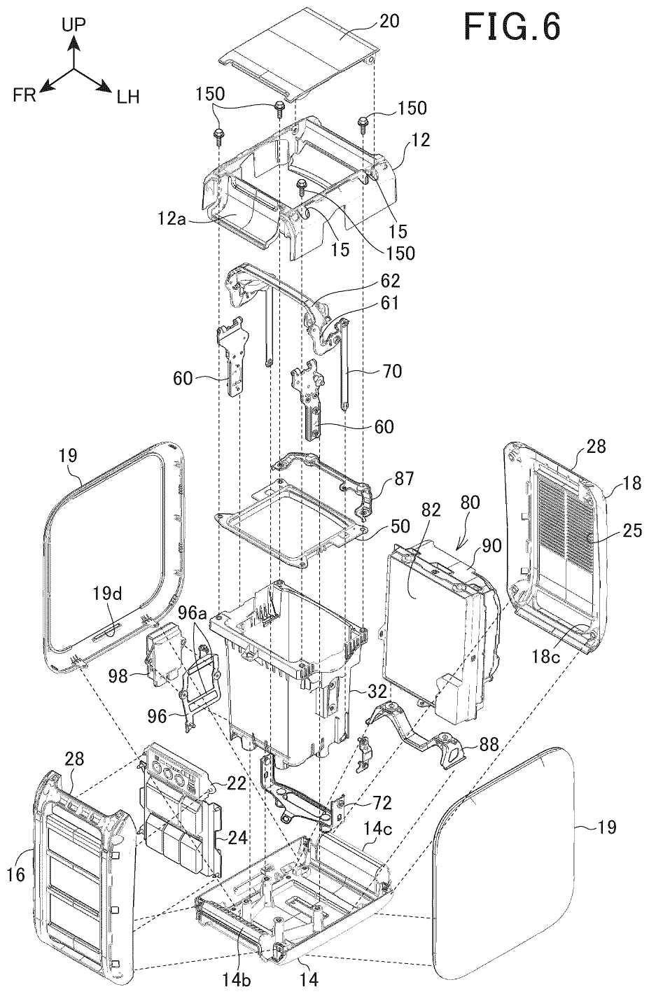

A front surface plate 12a is provided on a front end of the upper surface panel 12, the front surface plate 12a extending toward a lower portion of the housing 10. The front surface plate 12a extends downward, the front surface plate 12a is thereafter gently inclined, and the front surface plate 12a extends toward the front of the housing 10. The front surface plate 12a is formed so as to draw an arc seen from a left-right direction of the housing 10. Similarly, a rear surface plate 12b is provided on a rear end of the upper surface panel 12, the rear surface plate 12b extending toward a lower portion of the housing 10. The rear surface plate 12b extends downward, the rear surface plate 12b is thereafter gently inclined, and the rear surface plate 12b extends toward the rear of the housing 10. The rear surface plate 12b is formed so as to draw an arc seen from a left-right direction of the housing 10 (FIG. 6).

A rectangular shaped cover body 20 is provided on the upper surface panel 12, the rectangular shape being in a planar view. The cover body 20 is rotatably fixed to an edge portion of the upper surface recessed portion 11, the edge portion being positioned on a rear side of the upper surface panel 12. The cover body 20 covers the entire upper surface recessed portion 11 and the entire upper surface opening 13, and the cover body 20 can be opened, by having a user rotate the cover body 20. On the upper surface panel 12, an upper surface of this cover body 20 forms a greater portion of the upper surface of the housing 10. The cover body 20 corresponds to a “covering portion”.

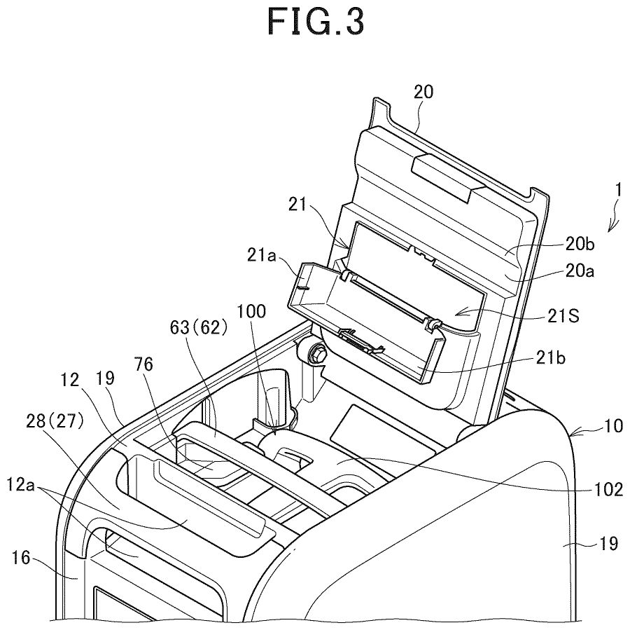

FIG. 3 is a perspective view showing an upper portion of the accommodation device 1. An expanded portion 21 is provided, on a lower surface opposite the upper surface opening 13, on the cover body 20, the expanded portion 21 being formed by having substantially the entire surface of the lower surface expanded toward the upper surface opening 13. According to this, the strength of the cover body 20 increases, and the housing 10 and the cover body 20 have an external pressure toughness from the outside that is improved. Namely, the expanded portion 21 functions as a reinforcement member of the cover body 20. In this expanded portion 21, the inside is formed hollow, and an inside space 21S is provided. A cover portion 21a is formed, at a front surface side of the housing 10, on the expanded portion 21, the cover portion 21a capable of being opened and closed by rotating with respect to a rear surface side of the expanded portion 21 in the housing 10.

As shown in FIG. 3, according to this, in the accommodation device 1, in a state where the cover body 20 is opened, when the cover portion 21a is opened, the expanded portion 21 opens toward the upside. Accordingly, in the accommodation device 1, it becomes easy for a user to insert and remove a predetermined item from the inside of the expanded portion 21. It is possible to store various types of cables, such as an electrical power cable for inputting electrical power from the outside to the accommodation device 1, for example, inside the expanded portion 21. The cover portion 21a corresponds to an “opening and closing portion”.

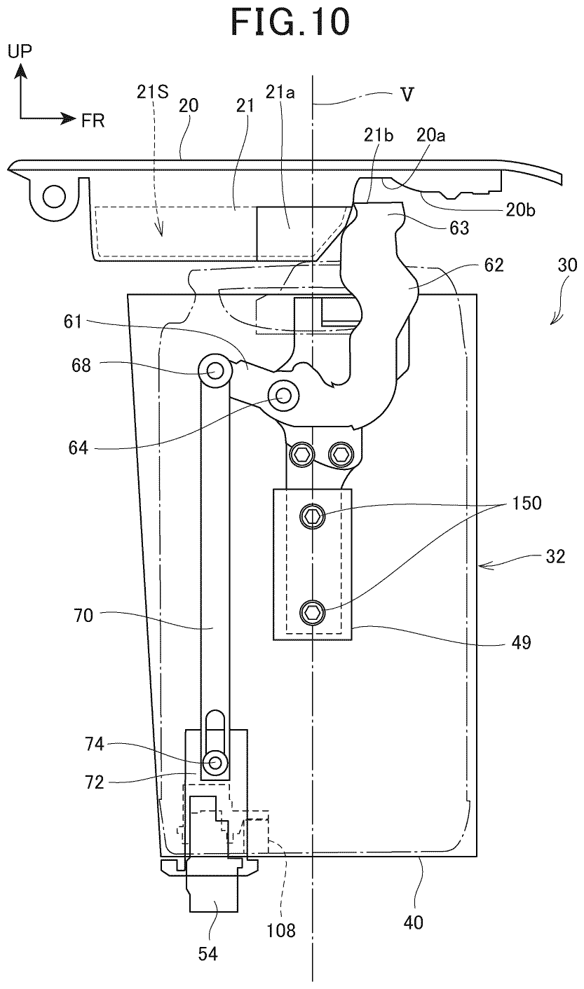

A chamfered portion 21b is provided, at a front surface side in the housing 10 and at a lower portion side of the housing 10, on the cover portion 21a, the chamfered portion 21b being formed by having corner portions of the cover portion 21a chamfered, seen from the side of the housing 10 (FIG. 7, FIG. 10). The chamfered portion 21b is provided across the entire width direction of the cover portion 21a extending along a left-right direction of the housing 10.

A cover body recessed portion 20a is provided, at a location positioned more on a front surface side of the housing 10 than the expanded portion 21, on a lower surface of the cover body 20 opposite the upper surface opening 13. The cover body recessed portion 20a is formed by having a lower surface of the cover body 20 linearly recessed toward the upside of the housing 10. The cover body recessed portion 20a is provided across the entire width direction of the cover portion 21a along a left-right direction of the housing 10. A chamfered portion 20b is provided, at a position opposite the expanded portion 21, on an inner side surface of the cover body recessed portion 20a, the chamfered portion 20b being formed by having an inner side surface of the cover body recessed portion 20a chamfered, seen from the side of the housing 10 (FIG. 10). The chamfered portion 20b is provided across the entire width direction of the cover body recessed portion 20a extending along a left-right direction of the housing 10.

An opening inclined surface 13a is provided, from the rear to the front of the housing, at an edge portion of the upper surface opening 13 positioned on a rear side of the housing 10, on the upper surface panel 12, the opening inclined surface 13a being an inclined surface that is gently inclined. An upper end of the opening inclined surface 13a is positioned on the rear of the cover body 20, and the upper end of the opening inclined surface 13a is coupled to an upper end of the rear surface plate 12b. The opening inclined surface 13a is inclined to a position substantially the same as a lower end of the upper surface panel 12, along a thickness direction of the upper surface panel 12, on an inner side of the upper surface opening 13.

The lower surface panel 14 is a member formed so as to include a predetermined thickness dimension, by folding each edge portion of a substantially rectangular plate shaped material upward along an up-down direction of the accommodation device 1. A flat surface 14a is provided at a substantial center of the lower surface panel 14. A hand hooking portion 14b and a hand hooking portion 14c are provided on each of a front end and a rear end of the lower surface panel 14.

The hand hooking portion 14b is erected from a front end of the lower surface panel 14 toward the upside of the housing 10, and thereafter the hand hooking portion 14b extends to a front surface side of the housing 10, while the hand hooking portion 14b is bent in a so-called arch shape, seen from a left-right direction of the housing 10, the so-called arch shape being a projecting shape drawing an arc toward the upside. Similarly, the hand hooking portion 14c is erected from a rear end of the lower surface panel 14 toward the upside of the housing 10, and thereafter the hand hooking portion 14c extends to a rear surface side of the housing 10, while the hand hooking portion 14c is bent in a so-called arch shape, seen from a left-right direction of the housing 10, the so-called arch shape being a projecting shape drawing an arc toward the upside. A tip end of each of the hand hooking portion 14b and the hand hooking portion 14c is positioned more upward than the flat surface 14a of the lower surface panel 14. A user can transport the accommodation device 1, by having the user place his or her fingers or hands on the hand hooking portion 14b and the hand hooking portion 14c.

A front surface air intake slot 23 is provided, at a location erected from a front end of the lower surface panel 14 toward the upside of the housing 10, on the hand hooking portion 14b, the front surface air intake slot 23 being a through hole. This front surface air intake slot 23 is formed in a long hole shape extending along a left-right direction of the housing 10. An upper edge of the front surface air intake slot 23 is positioned more downward than the tip end of the hand hooking portion 14b.

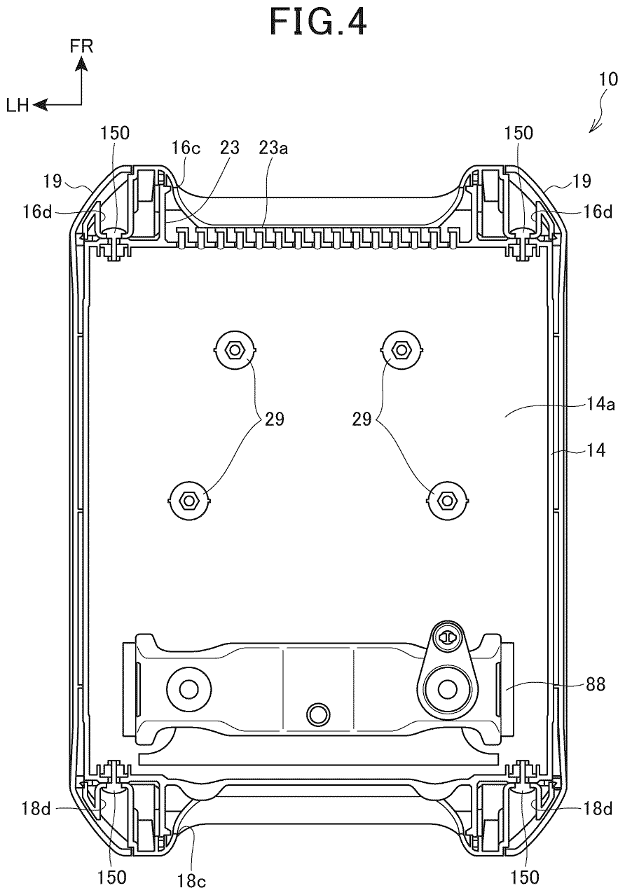

FIG. 4 is a horizontal cross-section view in which the accommodation device 1 is cut at Plane IV shown in FIG. 1. In FIG. 4, a state is shown in which the horizontal cross-section is in a planar view. A plurality of louvers 23a is provided on the front surface air intake slot 23. As shown in FIG. 4, each of the louvers 23a is formed in a shape drawing an S shape in a planar view. Each of the louvers 23a is disposed so that a tip end of a front surface side of the housing 10 overlaps a rear end of another adjacent one of the louvers 23a. According to this, a so-called labyrinth structure is formed, from a front surface side to a rear surface side of the housing 10, on the front surface air intake slot 23. According to this, in the housing 10, foreign objects such as dust and garbage entering the inside from the outside of the housing 10, via the front surface air intake slot 23, is suppressed.

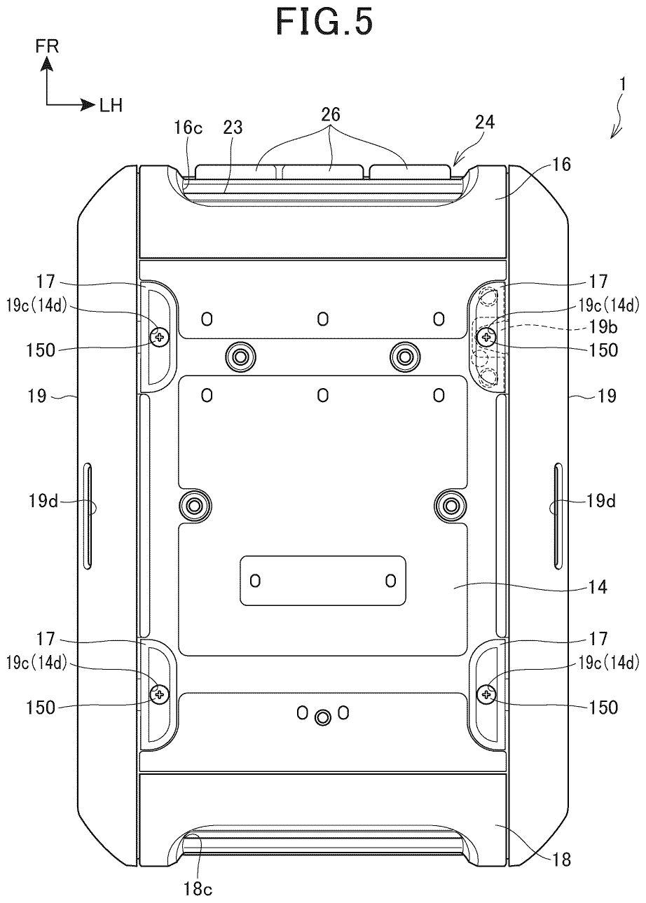

FIG. 5 is a figure in which the accommodation device 1 is seen from a lower surface side. As shown in FIG. 5, a plurality of screw holes 14d is provided on the lower surface panel 14. The screw holes 14d are provided, along each of each side positioned in a left-right direction of the housing 10, on the lower surface panel 14, the screw holes 14d being provided in sets of two.

As shown in FIG. 2, the front surface panel 16 is a member formed so as to include a predetermined thickness dimension, by having each edge portion of a substantially rectangular plate shaped material folded to the rear side so as to form a curved surface, along a front-rear direction of the accommodation device 1. A flat surface 16a is provided at a substantial center of the front surface panel 16. A unit opening 16b is provided on the flat surface 16a, the unit opening 16b being a through hole. In the present embodiment, the unit opening 16b is a rectangular long hole extending along a left-right direction of the housing 10, and three of the unit openings 16b are provided, along an up-down direction of the housing 10.

A front surface opening 16c is formed more downward than the unit opening 16b, the front surface opening 16c being a rectangular long hole extending along a left-right direction of the housing 10.

A rod-shaped handle 28 is provided, at a position more in the vicinity of an upper surface side than a lower surface side of the housing 10, on the front surface panel 16, the rod-shaped handle 28 extending along a left-right direction of the housing 10. A lower edge of the handle 28 is formed, on a front surface side of the housing 10, by having a portion positioned more upward than the unit opening 16b hollowed out into a long hole shape. An upper edge of the handle 28 is formed by having a substantial center of an upper end of the front surface panel 16 notched along an up-down direction of the housing 10. According to this, each of the handles 28 is provided without protruding from each surface of the housing 10. Accordingly, it is possible to improve designability and operability of the accommodation device 1.

The handle 28 is formed hollow. A side surface is integrally formed with the front surface panel 16, on this handle 28, the side surface being coupled from a position opposite the rear across a position opposite the bottom. A plurality of ribs 28a is provided on the inside of the handle 28, the plurality of ribs 28a extending erected in a direction orthogonal to a longitudinal direction of the handle 28. According to this, it is possible for the handle 28 to include a predetermined strength. A side surface positioned on an outer side of the accommodation device 1 is formed, on the handle 28, by a handle cover 27 separate from the front surface panel 16. The handle cover 27 is attached to the front surface panel 16. According to this, it is possible for the handle 28 to be formed hollow, and it is possible for the handle 28 to be reduced in weight.

It becomes possible for a user to transport or install the accommodation device 1 by holding these handles 28. Note that, the handle 28 is not limited to a shape in which the user can grip the entire circumference, such as stated above, and the handle 28 may have another shape, for example, in which a user can hold the accommodation device 1 by the user placing his or her fingers or hands, such as a groove shape. Namely, the accommodation device 1 may have a recessed portion or the like that is provided so as to become a hand hook for a user to hold. The handle 28 provided on the front surface panel 16 corresponds to a “first handle”, and the handle 28 provided on the rear surface panel 18 corresponds to a “second handle”.

Screw holes 16d are provided, at portions adjacent to each corner portion of the flat surface 16a, on the front surface panel 16. Engagement holes 16e are provided, at each edge portion extending along an up-down direction of the housing 10, on the flat surface 16a, the engagement holes 16e being recessed portions with which a claw shaped member can engage.

The rear surface panel 18 is a member formed so as to include a predetermined thickness dimension, by folding each edge portion of a substantially rectangular plate shaped member to the front side so as to form a curved surface, along a front-rear direction of the accommodation device 1. A flat surface 18a is provided at a substantial center of the rear surface panel 18. A rear surface discharge slot 25 is provided on the flat surface 18a, the rear surface discharge slot 25 being a through hole. In the present embodiment, the rear surface discharge slot 25 is formed in a rectangular shape in a planar view of the rear surface panel 18, and the rear surface discharge slot 25 is provided at a position more in the vicinity of an upper surface side than a lower surface side of the housing 10. A plurality of louvers is provided on the rear surface discharge slot 25. Note that, at least either the front surface panel 16 or the rear surface panel 18 is not limited to one member, and at least either the front surface panel 16 or the rear surface panel 18 may be formed from two or more members.

As shown in FIG. 4 and FIG. 5, a rear surface opening 18c is formed more downward than the rear surface discharge slot 25, the rear surface opening 18c being a rectangular long hole extending along a left-right direction of the housing 10.

As shown in FIG. 2, a rod-shaped handle 28 is provided, at a position more in the vicinity of an upper surface side than a lower surface side of the housing 10, on the rear surface panel 18, the rod-shaped handle 28 extending along a left-right direction of the housing 10. The handle 28 of the rear surface panel 18 is formed in substantially the same shape as the handle 28 of the front surface panel 16. A lower edge of the handle 28 is formed, on a front surface side of the housing 10, by having a portion positioned more upward than the rear surface discharge slot 25 hollowed out into a long hole shape. An upper edge of the handle 28 is formed by having a substantial center of an upper end of the rear surface panel 18 notched along an up-down direction of the housing 10.

The handle 28 is formed hollow. A side surface is integrally formed with the rear surface panel 18, on this handle 28, the side surface being coupled from a position opposite the front across a position opposite the bottom. A plurality of ribs 28a is provided on the inside of the handle 28, the plurality of ribs 28a extending erected in a direction orthogonal to a longitudinal direction of the handle 28. A side surface positioned on an outer side of the accommodation device 1 is formed, on the handle 28, by a handle cover 27 separate from the rear surface panel 18. The handle cover 27 is attached to the rear surface panel 18.

Screw holes 18d are provided, at portions adjacent to each corner portion of the flat surface 18a, on the rear surface panel 18. Engagement holes 18e are provided, at each edge portion extending along an up-down direction of the housing 10, on the flat surface 18a, the engagement holes 18e being recessed portions with which a claw shaped member can engage.

As shown in FIG. 1 and FIG. 2, an upper end of the front surface panel 16 is coupled to a front end of the upper surface panel 12, and an upper end of the rear surface panel 18 is coupled to a rear end of the upper surface panel 12. A lower end of the front surface panel 16 is coupled to a front end of the lower surface panel 14, and a lower end of the rear surface panel 18 is coupled to a rear end of the lower surface panel 14.

Specifically, a fastening member 150 is screwed into a front end of the upper surface panel 12, the fastening member 150 being inserted into each of the screw holes 16d on an upper end side of the front surface panel 16, and a fastening member 150 is screwed into a front end of the lower surface panel 14, the fastening member 150 being inserted into each of the screw holes 16d on a lower end side of the front surface panel 16. Similarly, a fastening member 150 is screwed into a rear end of the upper surface panel 12, the fastening member 150 being inserted into each of the screw holes 18d on the upper end side of the rear surface panel 18, and a fastening member 150 is screwed into a rear end of the lower surface panel 14, the fastening member 150 being inserted into each of the screw holes 18d on a lower end side of the rear surface panel 18.

According to this, the upper surface panel 12, the lower surface panel 14, the front surface panel 16, and the rear surface panel 18 are coupled to one another so as to become a rectangular frame shape, in a view from a left-right direction of the housing 10 (FIG. 6). Accordingly, each panel reinforces one another, and therefore it is possible to perform an increase in the strength of the accommodation device 1. In addition, since the front surface panel 16 and the rear surface panel 18 are fixed to the upper surface panel 12 and the lower surface panel 14, the handles 28 being provided on the front surface panel 16 and the rear surface panel 18, the strength of the accommodation device 1 is secured in the case where a user transports the accommodation device 1 by the user holding the handles 28.

When the upper surface panel 12 and the front surface panel 16 are coupled, a circumferential surface of the handle 28 and the front surface plate 12a are disposed opposite one another. A tip end of the front surface plate 12a extends to below the handle 28, and the front surface plate 12a forms a curved surfaces opposite the circumferential surface of the handle 28. Similarly, when the upper surface panel 12 and the rear surface panel 18 are coupled, a circumferential surface of the handle 28 and the rear surface plate 12b are disposed opposite one another. A tip end of the rear surface plate 12b extends to below the handle 28, and the rear surface plate 12b forms a curved surface opposite the circumferential surface of the handle 28.

In the case where a user holds each of the handles 28, a hand is inserted between each of the handles 28 and either the front surface plate 12a or the rear surface plate 12b. The front surface plate 12a and the rear surface plate 12b are formed from one member, and the front surface plate 12a and the rear surface plate 12b form a jointless curved surface. Accordingly, in the accommodation device 1, in the case where a hand is inserted between each of the handles 28 and either the front surface plate 12a or the rear surface plate 12b, a joint or the like does not come into contact with the hand of the user.

When the lower surface panel 14 and the front surface panel 16 are coupled, the hand hooking portion 14b and the front surface air intake slot 23 are exposed on a front surface side of the housing 10, via the front surface opening 16c. A tip end of the hand hooking portion 14b is coupled to an upper edge of the front surface opening 16c. Similarly, when the lower surface panel 14 and the front surface panel 16 are coupled, the hand hooking portion 14c is exposed on a rear surface side of the housing 10, via the rear surface opening 18c. A tip end of the hand hooking portion 14c is coupled to an upper edge of the rear surface opening 18c.

It is possible for a user to transport the accommodation device 1, by having the user place his or her fingers or hands on the hand hooking portion 14b and the hand hooking portion 14c, via the front surface opening 16c or the rear surface opening 18c. The hand hooking portion 14b corresponds to a “third handle”. The hand hooking portion 14c corresponds to a “fourth handle”.

Each of the side surface panels 19 is a substantially rectangular plate shaped member in a planar view. An inclined surface is formed, from each side toward flat surfaces of the housing 10, the flat surfaces being left and right side surfaces, on each of the corner portions of the side surface panels 19, the inclined surface being gently inclined. When each of the side surface panels 19 is coupled to the other panels, each of the inclined surfaces becomes a surface connected to each of the upper surface, the lower surface, the front surface, and the rear surface of the housing 10. On each of the side surface panels 19, the flat surface positioned in the center is a flat portion, and the flat surface functions as a main surface for forming a greater portion of a side surface around the housing 10.

A plurality of engagement pieces 19a is provided, on each of three sides, on each of the side surface panels 19, the three sides excluding the side positioned on a lower end side of the housing 10 in an up-down direction, the plurality of engagement pieces 19a protruding from a surface positioned on an inner side of the housing 10. Each of the side surface panels 19 is attached to each of these panels, by engaging each of these engagement pieces 19a, from both the left and right, with each of the engagement holes 12c of the upper surface panel 12, each of the engagement holes 16e of the front surface panel 16, and each of the engagement holes 18e of the rear surface panel 18. Note that, the present invention is not limited to this, and each of the side surface panels 19 may be fixed to each panel by using a fastening member. Moreover, for example, at least one of each of the side surface panels 19 is not limited to one member, and at least one of each of the side surface panels 19 may be formed from two or more members.

The accommodation device 1 can be installed with one of the left-right side surfaces, namely, one of each of the side surface panels 19, as a bottom surface. Hereinafter, a so-called lying posture is called a second posture, the so-called lying posture being a state where the accommodation device 1 is installed with one of the left-right side surfaces as a bottom surface.

As shown in FIG. 6, a plurality of fixing pieces 19b is provided, on a side positioned on a lower end side of the housing 10 in an up-down direction, on each of the side surface panels 19, the plurality of fixing pieces 19b protruding in a same direction as the engagement pieces 19a. A screw hole 19c is provided on each of the fixing pieces 19b. When each of the side surface panels 19 is attached to the upper surface panel 12, the lower surface panel 14, the front surface panel 16, and the rear surface panel 18, each of the fixing pieces 19b is disposed below the flat surface 14a of the lower surface panel 14, and each of the screw holes 19c is disposed below each of the screw holes 14d.

A plurality of leg portions 17 is provided at locations where the flat surface 14a and each of the fixing pieces 19b are overlapping, the plurality of leg portions 17 protruding toward a lower surface leg portion outside. Each of the leg portions 17 is attached to the lower surface panel 14, by having each of the leg portions 17 fastened together to each of the screw holes 19c and each of the screw holes 14d, by each of the fastening members 150. In addition, each of the side surface panels 19 and the lower surface panel 14 are fixed. In the first posture, the accommodation device 1 is supported by these leg portions 17. In the first posture, the lower surface panel 14 is disposed vertically downward, in an up-down direction of the housing 10.

As shown in FIG. 1 and FIG. 6, a water drain hole 19d is provided, at a boundary between the inclined surface positioned on a lower end side of the housing 10 in an up-down direction and the flat surface positioned in the center of the housing 10 in an up-down direction, on each of the side surface panels 19, the water drain hole 19d being a through hole. The water drain hole 19d is a long hole extending along a front-rear direction of the housing 10.

In the case where the accommodation device 1 is installed in the first posture, each of the water drain holes 19d is disposed at a position in the vicinity of the lower surface panel 14, in an up-down direction of the housing 10. Accordingly, in the accommodation device 1 disposed in the first posture, moisture entering the inside or moisture caused by condensation is drained from each of the water drain holes 19d.

The accommodation device 1 can be installed with one of the left-right side surfaces, namely, one of each of the side surface panels 19, as a bottom surface. In this case, either of the water drain holes 19d is disposed at a position substantially the same as an installation surface of the accommodation device 1. Accordingly, in the accommodation device 1, moisture entering the inside or moisture caused by condensation is drained from each of the water drain holes 19d. Hereinafter, a state in which the accommodation device 1 is installed with one of the left and right side surfaces as a bottom surface is called a second posture.

In this way, it is possible for the accommodation device 1 to drain moisture on the inside, in an installation state of either the first posture or the second posture, by having the water drain holes 19d provided.

As shown in FIG. 1 and FIG. 6, a seal material 19e is provided, at a boundary between the inclined surface and the flat surface positioned in the center, on each of the side surface panels 19. The seal material 19e is formed, for example, by a rubber material or the like. The seal material 19e seals a gap between each of the side surface panels 19, the upper surface panel 12, the lower surface panel 14, the front surface panel 16, and the rear surface panel 18. According to this, in the accommodation device 1, moisture, garbage or the like entering the inside of the housing 10 from a gap between each of the side surface panels 19, the upper surface panel 12, the lower surface panel 14, the front surface panel 16, and the rear surface panel 18, is suppressed. Each of the seal materials 19e is provided by being omitted at a position overlapping each of the water drain holes 19d.

As shown in FIG. 1 and FIG. 6, when each of the side surface panels 19 is attached to the upper surface panel 12, the lower surface panel 14, the front surface panel 16, and the rear surface panel 18, each of the screw holes 16d and each of the screw holes 18d are covered by each of the side surface panels 19.

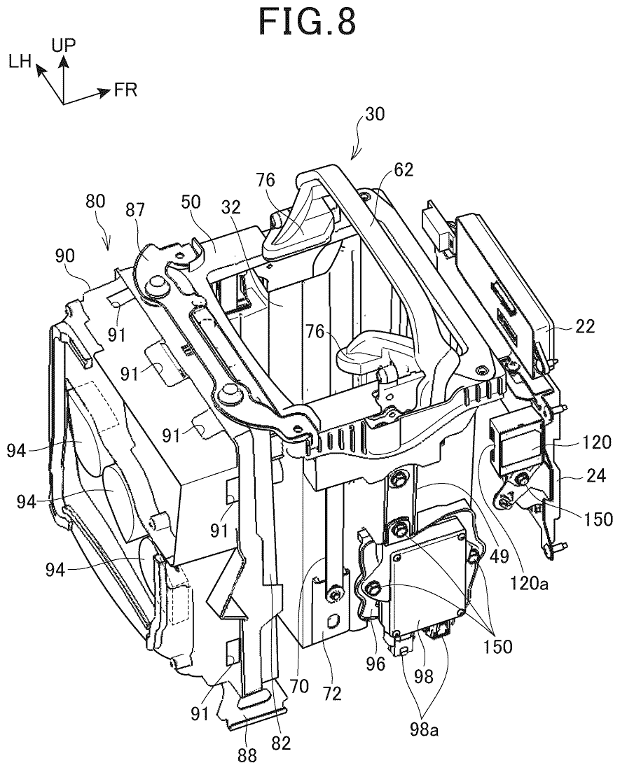

FIG. 6 is an exploded perspective view of the accommodation device 1. FIG. 7 is a longitudinal cross-section view in which the accommodation device 1 is cut at Plane VII shown in FIG. 1. Plane VII is a virtual surface passing through a substantial center of the accommodation device 1 in a left-right direction. In FIG. 7, for convenience of the description, the battery 100 and the expanded portion 21 are shown by a one-dot chain line, and the processor 130 is shown by a two-dot chain line. FIG. 8 is a perspective view showing the members stored in the accommodation device 1. As shown in FIG. 6, FIG. 7, and FIG. 8, the accommodation mechanism 30 is provided inside the housing 10, the accommodation mechanism 30 for accommodating the battery 100. The accommodation mechanism 30 is disposed, at a substantial center, in the front-rear direction of the housing 10, and the accommodation mechanism 30 is positioned directly below the upper surface opening 13.

As shown in FIG. 1, a user interface unit 22 is provided, positioned more in the vicinity of an upper surface side than a lower surface side, on the front surface panel 16, the user interface unit 22 being positioned on a front surface of the housing 10. The user interface unit 22 includes a display area on which Light Emitting Diodes (LEDs) or the like are provided, the display area displaying an operation state of the accommodation device 1, a remaining amount of energy of the battery 100 or the like, and the user interface unit 22 includes a switch area on which a switch is provided, the switch being an operator for receiving an operation, such as a switching instruction of an operation state of the accommodation device 1, from a user. Note that, the user interface unit 22 is not limited to a physical switch, and the user interface unit 22 may be formed to be operatable by a touch panel provided on the display area. The display area corresponds to a “display portion”, and the switch area corresponds to an “operation portion”. The user interface unit 22 corresponds to an “interface portion”.

A terminal unit 24 is provided, more downward than the user interface unit 22, on the front surface panel 16. The terminal unit 24 includes an AC power output terminal and a DC power output terminal. The AC power output terminal and the DC power output terminal supply AC power and DC power to another electric device or the like, via outside terminals that are respectively connected to the AC power output terminal and the DC power output terminal. The terminal unit 24 includes an operator for receiving a predetermined operation with respect to the accommodation device 1, and the terminal unit 24 includes a connection terminal connected to another accommodation device 1.

The terminal unit 24 includes an AC power input terminal and a DC power input terminal. AC power or DC power is supplied from a power generating device outside the accommodation device 1, such as an AC output portion (outlet) of a generator, a house or the like, or a solar panel, via external terminals respectively connected to the AC power input terminal and the DC power input terminal. It is possible for the accommodation device 1 to perform charging of the battery 100 accommodated inside, by using the input AC power or DC power. Namely, the accommodation device 1 functions as a charging device.

A cover member 26 is provided on the terminal unit 24, the cover member 26 covering each of the above-stated various terminals and operator. The cover member 26 is provided to be capable of attaching/detaching to/from the terminal unit 24. Note that, the cover member 26 may be integrally provided with the terminal unit 24, and the cover member 26 may be formed to be capable of opening/closing.

A communication unit 120 is provided in the terminal unit 24. The communication unit 120 includes communication hardware compliant with short-range wireless communication standards, such as an antenna or a communication circuit. It is possible for the communication unit 120 to communicate, for example, with a terminal device such as a remote control, a smartphone, or a tablet. In the accommodation device 1, it is possible to display the same display as a display area on a display portion of a terminal device such as a display, and it is possible to perform the same operation as an operation by a switch area by the terminal device, by communicating between the terminal device and the communication unit 120. Note that, Wi-Fi (Registered Trademark) or Bluetooth (Registered Trademark) or the like are provided, in this example, as short-range wireless communication standards. The communication unit 120 is attached to the side of the terminal unit 24, and the communication unit 120 is provided at a position of the housing 10 not exposed to the outside.

The user interface unit 22, the terminal unit 24, and the communication unit 120 are attached to a flat surface of the front surface panel 16 on the rear side in the housing 10, in a state where the user interface unit 22, the terminal unit 24, and the communication unit 120 are coupled to one another beforehand. In the user interface unit 22 and the terminal unit 24 attached in such a way, the display area, the switch area, the various types of terminals, and the operator are exposed to a front surface side of the housing 10, by inserting the display area, the switch area, the various types of terminals, and the operator into the unit opening 16b.

In the present embodiment, the communication unit 120 is attached to the terminal unit 24 by the fastening member 150. This fastening member 150 is attached so that a screw head included in the fastening member 150 faces the side surface panel 19 forming a right side surface of the housing 10. Moreover, the communication unit 120 and the fastening member 150 are each disposed at a position exposed to the outside, in the case where the side surface panel 19 is removed.

A communication unit terminal 120a is provided in the communication unit 120, the communication unit terminal 120a being capable of connecting a terminal of predetermined wiring or the like. The communication unit terminal 120a is a female-shaped terminal provided so as to be opened toward the rear of the housing 10, along a front-rear direction of the housing 10. Note that, the present invention is not limited to this, and the communication unit terminal 120a may be a male-shaped terminal provided so as to protrude toward the rear of the housing 10, along a front-rear direction of the housing 10.

An inverter unit 80 is provided, on the rear of the accommodation mechanism 30, in a front-rear direction of the housing 10. The inverter unit 80 includes an inverter 82 and a shroud 90. The inverter 82 functions as a so-called DC-AC inverter, in which the inverter 82 converts DC power supplied from the battery 100 in accordance with an operation of a user, and the inverter 82 outputs AC power.

The inverter 82 includes a rectangular substrate 84 on which predetermined electrical components 86 are mounted on both surfaces. The substrate 84 is disposed so that each flat surface faces a front-rear direction of the housing 10. The electrical components 86 form a predetermined electrical circuit, such as an inverter circuit or a convertor circuit. Another electrical operation portion is mounted on the substrate 84, the other electrical operation portion being an AC-DC converter, a DC-DC converter or the like. Accordingly, it is possible for the inverter 82 to convert, for example, DC power supplied from the battery 100, and it is possible for the inverter 82 to output DC power of a different voltage. The inverter 82 corresponds to an “energy conversion portion”.

As stated above, the accommodation device 1 has AC power or DC power that is supplied from a power generating device outside the accommodation device 1, via the terminal unit 24. AC power input to the accommodation device 1 is converted into DC power by the AC-DC converter included in the inverter 82, and this DC power is charged into the battery 100. DC power input to the accommodation device 1 converts a voltage by the DC-DC converter included in the inverter 82, and this voltage is charged into the battery 100.

The shroud 90 is a covering member that covers the inverter 82 from the rear, in a front-rear direction of the housing 10. A plurality of air blowers 92 is provided on the shroud 90, the plurality of air blowers 92 cooling the battery 100 and the inverter 82.

A plurality of shroud air intake slots 91 is provided, at locations covering a circumferential edge of the inverter 82, on the shroud 90, the plurality of shroud air intake slots 91 being through holes. The shroud air intake slots 91 each communicate between an inside space of the shroud 90 and the outside of the inverter unit 80.

The inverter unit 80 is fixed to the inside of the housing 10, by having an upper edge of the substrate 84 supported by an upper edge support member 87, and having a lower edge of the substrate 84 supported by a lower edge support member 88. The upper edge support member 87 is a linear member curved in a U-shape toward the rear, in a front-rear direction of the housing 10. The upper edge support member 87 has both ends that are fixed to the accommodation mechanism 30, and the upper edge support member 87 supports the substrate 84 and the inverter unit 80 by coming into contact with the substrate 84 at two locations positioned at a substantial center in a longitudinal direction.

The lower edge support member 88 is provided on the lower surface panel 14, and the lower edge support member 88 is a linear member extending along a left-right direction of the housing 10. The lower edge support member 88 is formed curved in a substantially M-shape, in a view from a front surface side of the housing 10, and the lower edge support member 88 supports the substrate 84 and the inverter unit 80 by having two apex portions come into contact with the substrate 84, the two apex portions protruding toward the upside of the housing 10. According to this, the inverter unit 80 is fixed to the housing 10.

As shown in FIG. 7, the battery 100 is a substantially rectangular parallelepiped electrical storage device in which an energy accumulator such as a battery cell is stored inside, the substantially rectangular parallelepiped electrical storage device being portable. Each of a pair of end surfaces 101, 103 positioned in a longitudinal direction of the battery 100 are rectangular in a planar view.

The battery 100 has a battery handle 102 that is provided on the one end surface 101 in a longitudinal direction, the battery handle 102 capable of being held by a user. The battery handle 102 is formed in a substantially T-shape in a planar view. A battery terminal 108 is provided on the other end surface 103. The battery terminal 108 is provided at a position in the vicinity of one side, on the end surface 103, and the battery terminal 108 is a female-shaped terminal also called a receptable, the female-shaped terminal extending along this side. The side of the end surface 103 on which the battery terminal 108 is disposed in the vicinity overlaps the side of the end surface 101 on which the side handle portion 104 is provided, in a planar view in a longitudinal direction of the battery 100. The battery terminal 108 corresponds to a “first electrical terminal”.

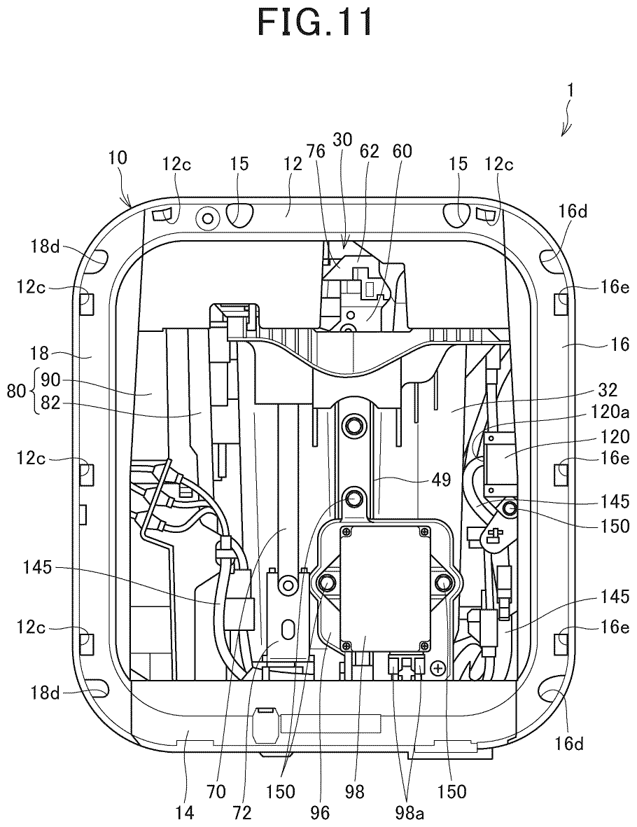

The battery 100 includes four battery side surfaces 107 extending along a longitudinal direction of the battery 100, both ends of each of the four battery side surfaces 107 being coupled to the end surfaces 101, 103 in a longitudinal direction. From among these battery side surfaces 107, one of the battery side surfaces 107 is formed in a curved surface shape, along a direction orthogonal to a longitudinal direction of the battery 100, in a view from a longitudinal direction of the battery 100, the curved surface shape being bent so as to draw a curved line. In contrast to this, the other battery side surfaces 107 are formed in a substantially flat shape. Namely, the battery 100 is formed in a rotationally asymmetrical shape through a center of the battery 100 in a planar view, and the battery 100 is formed in a rotationally asymmetrical shape with the virtual line V set as an axis of rotation, the virtual line V extending along a longitudinal direction of the battery 100 (FIG. 10, FIG. 11). Hereinafter, the battery side surface 107 formed in a curved surface shape is set as a curved surface 109. The curved surface 109 is coupled to a side of the end surface 103 on which the battery terminal 108 is disposed in the vicinity.

The battery 100 includes a processor 130 for performing control of the battery 100. The processor 130 switches between an activation state and a non-activation state of the battery 100. The activation state is a state capable of outputting electrical power of the battery 100 to the outside of the battery 100, and the activation state is a state capable of inputting electrical power of the outside of the battery 100 to the battery 100. The non-activation state is a state not capable of outputting electrical power of the battery 100 to the outside of the battery 100, and the non-activation state is a state not capable of inputting electrical power of the outside of the battery 100 to the battery 100. The battery 100 corresponds to a “portable energy accumulator, power accumulator”. The processor 130 corresponds to a “switching control portion”.

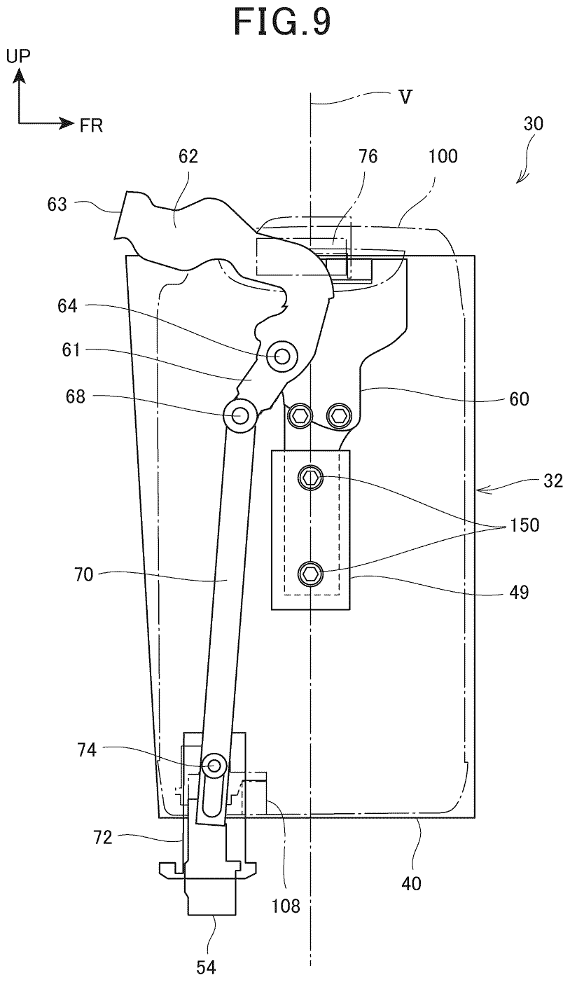

As shown in FIG. 7, FIG. 9, and FIG. 10, the accommodation mechanism 30 accommodates the battery 100, and the accommodation mechanism 30 is electrically connected to the battery terminal 108 of the battery 100. The accommodation mechanism 30 includes a battery case 32. The battery case 32 is a container made of resin, for example, the battery case 32 accommodating and holding the battery 100. The battery case 32 is formed in a substantially rectangular parallelepiped shape in which a longitudinal direction extends along an up-down direction of the housing 10.

The battery case 32 includes a back portion 40 forming a bottom surface on the inside of the battery case 32, and the battery case 32 includes side walls 48 erected from each side of the back portion 40. The back portion 40 is positioned on a lower portion side of the housing 10, and the back portion 40 corresponds to a lower end portion of the battery case 32. The back portion 40 is formed in a substantially rectangular shape in a planar view. Each of the side walls 48 forms each of the side surfaces of the battery case 32. Each of the side walls 48 is formed in a substantially rectangular shape in a planar view, and a longitudinal direction of each the side walls 48 extends along an up-down direction of the housing 10. In the present embodiment, a length dimension of the side walls 48 in a longitudinal direction is formed so as to be substantially the same as a length dimension of the battery side surface 107 in a longitudinal direction.

The battery case 32 includes a rectangular insertion/removal slot 31 on which the entire upper end surface is opened. The insertion/removal slot 31 is disposed at a position overlapping the upper surface opening 13, in a planar view of the housing 10. The battery case 32 corresponds to an “accommodation unit” in the present disclosure, and the insertion/removal slot 31 corresponds to an “opening” in the present disclosure.

A frame shaped projecting portion 34 is provided, on a circumferential edge of the insertion/removal slot 31, on the battery case 32, the frame shaped projecting portion 34 projecting to the outside in a predetermined width direction. The frame shaped projecting portion 34 is formed in a rectangular frame shape, in a planar view. A screw hole 33 is provided at each corner portion of the frame shaped projecting portion 34. A plate insertion hole 35 and a metal fitting insertion hole 37 are provided, at portions positioned in a left-right direction of the housing 10 across the insertion/removal slot 31, on the frame shaped projecting portion 34, the plate insertion hole 35 and the metal fitting insertion hole 37 both being a through hole.

The battery case 32 includes a rectangular back portion 40 in a planar view on an opposite side of the insertion/removal slot 31 in a longitudinal direction. A terminal hole 41 is provided on the back portion 40, the terminal hole 41 being a through hole passing through the inside and outside of the battery case 32. The terminal hole 41 is a long hole extending along one side positioned on a rear side of the housing 10, on the back portion 40.

As shown in FIG. 7, a plurality of case side bosses 38 is provided on the back portion 40 of the battery case 32, the plurality of case side bosses 38 protruding toward the outside of the battery case 32, and the plurality of case side bosses 38 protruding toward a lower portion side of the housing 10. Each of the case side bosses 38 has a tip end surface that is formed in a circular column shape. A screw hole is provided, along an extending direction of the case side bosses 38, in a substantial center in a planar view of each of the case side bosses 38, the screw hole being a through hole.

As shown in FIG. 6 and FIG. 8, a case frame body 50 is provided on the battery case 32, the case frame body 50 being a rectangular frame shaped member in a planar view. The case frame body 50 is formed, for example, by a material such as a metallic material, the material including at least either a higher strength than the battery case 32 or a higher rigidity than the battery case 32 such as a metallic material. Note that, the case frame body 50 may be formed by a material the same as a material of the battery case 32.

A frame body opening 51 is provided at the center of the case frame body 50. The frame body opening 51 is formed in a substantially same shape as a shape of a circumferential surface of the battery 100 seen from a longitudinal direction in a planar view. Accordingly, in the frame body opening 51, a side positioned on a rear side of the housing 10 is formed in a curved shape in a planar view, and the other sides are formed in a substantially linear shape. Note that, a length dimension of each side included in each of the upper surface opening 13 and the insertion/removal slot 31 is formed so as to become greater than or equal to the length dimension of each side of the frame body opening 51.

A screw hole 53 is provided on each corner portion of the case frame body 50. The case frame body 50 is attached to the battery case 32, by having each of the screw holes 53 and each of the screw holes 33 fastened together by the fastening member 150, in a state where each of the screw holes 53 and each of the screw holes 33 are mutually overlapping.

FIG. 9 and FIG. 10 are each a schematic view in which the accommodation mechanism 30 is seen from a right direction of the accommodation device 1. In FIG. 9 and FIG. 10, for convenience of the description, the battery 100 and a lock mechanism 76 are shown by a one-dot chain line, and a virtual line V is shown by a two-dot chain line, the virtual line V extending along a longitudinal direction of the battery 100, through the center of the battery 100 in a planar view. As shown in FIG. 8, FIG. 9, and FIG. 10, a pocket shaped metal fitting holding portion 49 is provided on each of the side walls 48 positioned on the left and right of the battery case 32, the pocket shaped metal fitting holding portion 49 having a space provided on the inside. An upper end of the metal fitting holding portion 49 is coupled to the metal fitting insertion hole 37.

A mounting metal fitting 60 is stored, via the metal fitting insertion hole 37, in each of the metal fitting holding portions 49. The mounting metal fitting 60 is a plate shaped member extending along an up-down direction of the housing 10. A lower portion side of each of the mounting metal fittings 60 is stored on the inside of the metal fitting holding portion 49, and the lower portion side of each of the mounting metal fittings 60 is fixed to the battery case 32 by the fastening member 150 inserted from outside the metal fitting holding portion 49. The upper end of each of the mounting metal fittings 60 is disposed more upward than the insertion/removal slot 31.

Each of the mounting metal fittings 60 rotatably supports a holding handle 62 along a front-rear direction of the housing 10. The holding handle 62 is a linear member included to extend along a left-right direction of the housing 10. The holding handle 62 is formed in a substantially U shape seen from the front of the housing 10, and both sides of the holding handle 62 in a longitudinal direction are rotatably attached to each of the mounting metal fittings 60, via a metal fitting shaft body 64. A lock plate 63 is disposed more upward than the insertion/removal slot 31 on a substantial center of the holding handle 62, the lock plate 63 extending linearly. The lock plate 63 is formed to enable the lock plate 63 to be held by a user. A link coupling end 61 is provided on both ends of the holding handle 62, the link coupling end 61 extending from the metal fitting shaft body 64 toward a rear side of the housing 10.

One end portion of a link plate 70 in a longitudinal direction is rotatably coupled, via the link shaft body 68, to a tip end of each of the link coupling ends 61. The link plate 70 is a plate shaped member extending along an up-down direction of the housing 10, outside of each of the side walls 48 positioned on the left and right. Each of the link plates 70 is held by the battery case 32, by having each of the link plates 70 inserted into the plate insertion hole 35.

Both ends of a terminal holding plate 72 in a longitudinal direction are rotatably coupled, via the plate shaft body 74, to each of the other end portions at which each of the link plates 70 are included. The terminal holding plate 72 is a plate shaped member including a predetermined length dimension. The terminal holding plate 72 is disposed along a lower portion of one of the side walls 48 at which one end portion in a longitudinal direction is positioned in a left-right direction. The terminal holding plate 72 is disposed along a lower portion of the one side wall 48 at which the other end portion is positioned in a left-right direction, through a lower side of the back portion 40 and the terminal hole 41 from a lower portion of the one side wall 48. Accordingly, the terminal holding plate 72 is formed folded in a substantially U shape in a front view of the housing 10. The holding handle 62, each of the link plates 70, and the terminal holding plate 72 each correspond to a “power transmission mechanism”.

A case side connection terminal 54 is provided, at a position opposite the terminal hole 41, on the terminal holding plate 72. The case side connection terminal 54 is a male-shaped terminal also called a plug, the male-shaped terminal being formed to be connectable to the battery terminal 108. The case side connection terminal 54 can be inserted into the terminal hole 41. The case side connection terminal 54 is electrically connected to the inverter 82 via predetermined wiring. Accordingly, when the case side connection terminal 54 is connected to the battery terminal 108, electrical power stored in the battery 100 is supplied to the inverter 82. The case side connection terminal 54 corresponds to a “second electrical terminal”.

As shown in FIG. 8, in the case where the lock plate 63 of the holding handle 62 moves to a rear side of the housing 10 with respect to the insertion/removal slot 31, each of the link coupling ends 61 moves to a lower portion side of the housing 10, and each of the link plates 70 and the terminal holding plate 72 move downward. According to this, the case side connection terminal 54 moves to the outside of the battery case 32, and the case side connection terminal 54 moves downward. The positions of the holding handle 62, each of the link plates 70, and the terminal holding plate 72 in this state each correspond to a “second position”.

As shown in FIG. 10, in the case where the lock plate 63 of the holding handle 62 moves to an upper portion side of the housing 10 with respect to the insertion/removal slot 31, each of the link coupling ends 61 moves to an upper portion side of the housing 10, and each of the link plates 70 and the terminal holding plate 72 move upward. According to this, the case side connection terminal 54 moves to the inside of the battery case 32, through the terminal hole 41. The positions of the holding handle 62, each of the link plates 70, and the terminal holding plate 72 in this state each correspond to a “first position”.

As shown in FIG. 8, the lock mechanism 76 is provided on an upper end of each of the mounting metal fittings 60. Each of the lock mechanisms 76 is rotatably attached along a left-right direction of the housing 10, on an upper end of the mounting metal fitting 60.

The lock mechanism 76 is positioned more on the insertion/removal slot 31 side than both ends of the holding handle 62. In the case where the lock plate 63 of the holding handle 62 is moved to an upper portion side of the housing 10 with respect to the insertion/removal slot 31, each of the lock mechanisms 76 has rotation that is restricted, by each of both ends of the holding handle 62, so that each of the lock mechanisms 76 becomes a position on the inside of the insertion/removal slot 31. The lock mechanism 76 corresponds to a “pressing portion”.

An activation battery 98 is provided, on one of the side walls 48 disposed along a left-right direction of the housing 10, on the battery case 32. The activation battery 98 is an electrical storage device for supplying electrical power to a processor or various types of electrical components for performing control of the accommodation device 1. When an operator for activating the accommodation device 1 is operated, this activation battery 98 supplies electrical power to the processor, and the accommodation device 1 is driven by having this processor start control of the accommodation device 1. The activation battery 98 supplies electrical power with a voltage lower than a voltage of the battery 100. The activation battery 98 corresponds to “another power accumulator”.

The activation battery 98 is attached to the battery case 32 via a fixing bracket 96. The fixing bracket 96 is fixed to each of the side walls 48 of the battery case 32, by having the fixing bracket 96 fastened together to the metal fitting holding portion 49, by the fastening member 150 for fixing the mounting metal fitting 60 to the metal fitting holding portion 49. The activation battery 98 is fixed to the fixing bracket 96 by the fastening member 150 such as a screw member.

A bracket buffering material 96a is provided, at a predetermined portion of a surface opposite the battery case 32, on the activation battery 98. The bracket buffering material 96a is formed by a material that includes flexibility such as a rubber material or a sponge material. The fixing bracket 96 comes into contact with the battery case 32 via this bracket buffering material 96a. Accordingly, in the case where transporting the accommodation device 1, or in the case where performing insertion or removal of the battery 100 with respect to the accommodation device 1, the activation battery 98 being vibrated is suppressed, by the bracket buffering material 96a, even in the case where the housing 10 vibrates.

In the accommodation device 1, the activation battery 98 is disposed between one of the side walls 48 and one of the side surface panels 19, and in the case where the side surface panel 19 is removed, the activation battery 98 is disposed at a position exposed to the outside.

An activation battery terminal 98a is provided on the activation battery 98, the activation battery terminal 98a being capable of connecting a terminal of a predetermined wiring or the like. The activation battery terminal 98a is a female-shaped terminal provided so as to be opened toward the downside of the housing 10, along an up-down direction of the housing 10. Note that, the present invention is not limited to this, and the activation battery terminal 98a may be a male-shaped terminal provided so as to protrude toward the downside of the housing 10, along an up-down direction of the housing 10.

FIG. 11 is a side surface view in which the accommodation device 1 is seen from the right side. In FIG. 11, the side surface panel 19 is omitted, the side surface panel 19 forming a right side surface. As shown in FIG. 11, a connection cable 145 is connected to both the communication unit terminal 120a and the activation battery terminal 98a. The connection cable 145 extends toward the rear of the housing 10, along the lower surface panel 14 of the housing 10, and another end of the connection cable 145 is connected to the inverter unit 80.

As stated above, in the case where the side surface panel 19 is removed, the communication unit 120 and the activation battery 98 are each disposed at a position exposed to the outside. A screw head included in the fastening member 150 is attached so as to face the side surface panel 19 forming a right side surface of the housing 10, the fastening member 150 for fixing each of the communication unit 120 and the activation battery 98. Similarly, the communication unit terminal 120a and the activation battery terminal 98a are each disposed at a position exposed to the outside, in the case where the side surface panel 19 is removed. Accordingly, in the accommodation device 1, by having the user remove one of the side surface panels 19, it is possible for the user to easily perform inspection or replacement of the communication unit 120, or it is possible for the user to easily perform a wiring connection process of the connection cable 145 or the like.

Here, a fixing structure of the housing 10 and the battery case 32 will be described. A plurality of panel side bosses 29 is provided on the lower surface panel 14, the plurality of panel side bosses 29 protruding toward the upside of the housing 10. Each of the panel side bosses 29 has a tip end surface that is formed in a circular column shape. Each of the panel side bosses 29 is disposed at a position corresponding to each of the case side bosses 38 in a planar view of the housing 10. Each of the panel side bosses 29 and each of the case side bosses 38 are fixed to one another, by coupling each of the panel side bosses 29 and each of the case side bosses 38 by the fastening member 150 inserted into the screw hole 39, in a state where the tip end surfaces abut on one another. According to this, the lower surface panel 14 and the battery case 32 are coupled, and the battery case 32 is disposed at a predetermined position, in an up-down direction of the housing 10.

The upper surface panel 12 and the battery case 32 are disposed so that each of the screw holes 15 and each of the screw holes 33 overlap in a planar view of the housing 10. In this state, the upper surface panel 12 and the battery case 32 are fixed, by having the fastening member 150 screwed into each of the screw holes 15 and each of the screw holes 33. According to this, in the accommodation device 1, the upper surface panel 12 and the lower surface panel 14 are coupled by the battery case 32. Accordingly, an improvement of the strength of the housing 10 can be performed.

As stated above, attachment to the battery case 32 is performed, by having the screw holes 53 of the case frame body 50 fastened together to each of the screw holes 33 by the fastening member 150. In addition, attachment to the battery case 32 is performed, by having both ends of the upper edge support member 87 fastened together to each of the screw holes 33 positioned on a rear side of the housing 10, by the fastening member 150. According to this, in the accommodation device 1, the upper surface panel 12, the battery case 32, the case frame body 50, and the upper edge support member 87 can be coupled, while suppressing an increase in the number of components.

In this way, in the accommodation device 1 for which an increase in the strength of the housing 10 is performed, the accommodation device 1 is not limited to the first posture, in which the accommodation device 1 is installed with a lower surface as a bottom surface in contact with an installation surface, and the accommodation device 1 can be installed with either an upper surface or a rear surface as a bottom surface. In addition, the accommodation device 1 can be installed in the second posture in which one of the left and right side surfaces is set as a bottom surface. According to this, it is possible for the accommodation device 1 to change an installation posture, in accordance with a usage of a user.

As shown in FIG. 6, the handle 28 of the rear surface panel 18 is disposed above the inverter unit 80, in an up-down direction of the housing 10, the inverter unit 80 being stored in the housing 10, and the hand hooking portion 14c is disposed below the inverter unit 80, in an up-down direction of the housing 10. The handle 28 of the front surface panel 16 is disposed above the user interface unit 22 and the terminal unit 24, in an up-down direction of the housing 10, the user interface unit 22 and the terminal unit 24 being stored in the housing 10, and the hand hooking portion 14b is disposed below the user interface unit 22 and the terminal unit 24, in an up-down direction of the housing 10.

The accommodation mechanism 30 is positioned between the pair of handles 28, and the accommodation mechanism 30 is positioned between the hand hooking portion 14b and the hand hooking portion 14c, in a planar view of the housing 10. The battery 100 is positioned between the handle 28 of the front surface panel 16 and the hand hooking portion 14b, in a view from a front surface of the housing 10, the battery 100 being stored in the accommodation mechanism 30. The battery 100 is positioned between the handle 28 of the rear surface panel 18 and the hand hooking portion 14c, in a view from a rear surface of the housing 10, the battery 100 being stored in the accommodation mechanism 30.

In other words, each of the pair of handles 28, the hand hooking portion 14b, and the hand hooking portion 14c is disposed at each of the corner portions of the housing 10, in a view from a left-right direction of the housing 10. Namely, each of the pair of handles 28, the hand hooking portion 14b, and the hand hooking portion 14c is provided in the housing 10, so that each of the pair of handles 28, the hand hooking portion 14b, and the hand hooking portion 14c surrounds the members stored in the accommodation device 1.

### (1.2. Operation)

An operation of the accommodation device 1 configured such as above will be described. In the case where the battery 100 is accommodated in the accommodation device 1, a user opens the cover body 20, and the user rotates the holding handle 62, so that the lock plate 63 is positioned at a predetermined position on a rear side of the housing 10 with respect to the insertion/removal slot 31. According to this, each of the lock mechanisms 76 is rotated along a left-right direction of the housing 10, and each of the lock mechanisms 76 moves to the outside of the insertion/removal slot 31 in a planar view.

Next, the user holds the battery handle 102, and the user performs insertion into the upper surface opening 13, the frame body opening 51, and the insertion/removal slot 31 from the other end surface 103 side, along the virtual line V. At this time, the user inserts the battery 100 in a posture in which the curved surface 109 is opposite a rear side of the housing 10. As shown in FIG. 9 and FIG. 10, in the case where the battery 100 is attached/detached to/from the accommodation mechanism 30, the attachment/detachment direction becomes a direction along the virtual line V extending along a longitudinal direction of the battery 100, through the center of the battery 100 in a planar view, the attachment/detachment direction being a direction of movement. In other words, the attachment/detachment direction is a direction along a longitudinal direction of the battery 100, and the attachment/detachment direction is a direction along a longitudinal direction of the battery case 32.

As stated above, only the side of the frame body opening 51 positioned on a rear side of the housing 10 is formed so as to be bent in an arc shape. Accordingly, only in the case where the user inserts the battery 100, in a posture in which the curved surface 109 is opposite a rear side of the housing 10, it is possible for the battery 100 to be inserted into the frame body opening 51. In contrast to this, in the case where the user inserts the battery 100 in a different posture to the above-stated posture, the battery 100 cannot pass through the frame body opening 51.

According to this, in the accommodation device 1, the battery terminal 108 and the case side connection terminal 54 being unable to be connected is suppressed, namely, the battery 100 being accommodated in a posture in which the battery 100 is unable to be electrically connected to the accommodation device 1 is suppressed. Accordingly, in the accommodation device 1, a connection defect of the accommodation device 1 and the battery 100 occurring is suppressed.

The battery 100 stored in the battery case 32 has only the end surface 101 positioned more upward than the insertion/removal slot 31. In other words, the battery 100 stored in the battery case 32 has the end surface 101 and the battery handle 102 exposed from the battery case 32.

When the battery 100 is stored in the battery case 32, the user rotates the holding handle 62, until the lock plate 63 is positioned at a predetermined position above the insertion/removal slot 31, such as shown in FIG. 10. In accordance with this rotation of the holding handle 62, each of the lock mechanisms 76 rotates along a left-right direction of the housing 10, each of the lock mechanisms 76 moves to the inside of the insertion/removal slot 31 in a planar view, and comes into contact with the end surface 101 of the battery 100. In addition, by rotation of the holding handle 62, the case side connection terminal 54 moves to the inside of the battery case 32, through the terminal hole 41, and the case side connection terminal 54 is connected to the battery terminal 108. According to this, the accommodation device 1 and the battery 100 are electrically connected.

Afterwards, the user rotates the cover body 20 to block the upper surface opening 13. At this time, as shown in FIG. 10, the holding handle 62 is disposed so as to fit inside the cover body recessed portion 20a. The expanded portion 21 is disposed on a rear side of the housing 10 with respect to the holding handle 62, and the portion where the chamfered portion 20b is provided on an inner side surface of the cover body recessed portion 20a is disposed on a front side of the housing 10 with respect to the holding handle 62. In this way, in the case where the cover body 20 blocks the upper surface opening 13, the holding handle 62 has rotation that is restricted, by having the holding handle 62 sandwiched by the expanded portion 21 and the cover body recessed portion 20a, in a front-rear direction of the housing 10. Accordingly, in the accommodation device 1, the accommodation device 1 and the battery 100 are electrically connected, and thereafter the holding handle 62 being rotated is restricted, even in the case where the accommodation device 1 is disposed in any posture.

In addition, since the chamfered portion 21b and the chamfered portion 20b are provided, in the case where the cover body 20 is rotated to block the upper surface opening 13, the expanded portion 21 and the cover body recessed portion 20a being in contact with the holding handle 62 is suppressed. According to this, the cover body 20 can be smoothly rotated to perform blocking, and rotation of the holding handle 62 can be restricted.

On the other hand, in the case where the lock plate 63 is not positioned at a predetermined position above the insertion/removal slot 31, namely, in the case where accommodation of the battery 100 is not completed by the accommodation mechanism 30, when the cover body 20 is rotated so as to block the upper surface opening 13, a lower surface of the expanded portion 21 comes into contact with the lock plate 63. According to this, the upper surface opening 13 being blocked by the cover body 20 is inhibited. Accordingly, in the accommodation device 1, in the case where accommodation of the battery 100 is not completed, use starting is suppressed.

As stated above, the holding handle 62 is provided so as to rotate along a front-rear direction of the housing 10, the holding handle 62 extending along a left-right direction of the housing 10.

When the holding handle 62 is rotated until the lock plate 63 rotates to an upper portion side of the housing 10 with respect to the insertion/removal slot 31, each of the lock mechanisms 76 has rotation that is restricted by the holding handle 62, and each of the lock mechanisms 76 presses the end surface 101 of the battery 100.

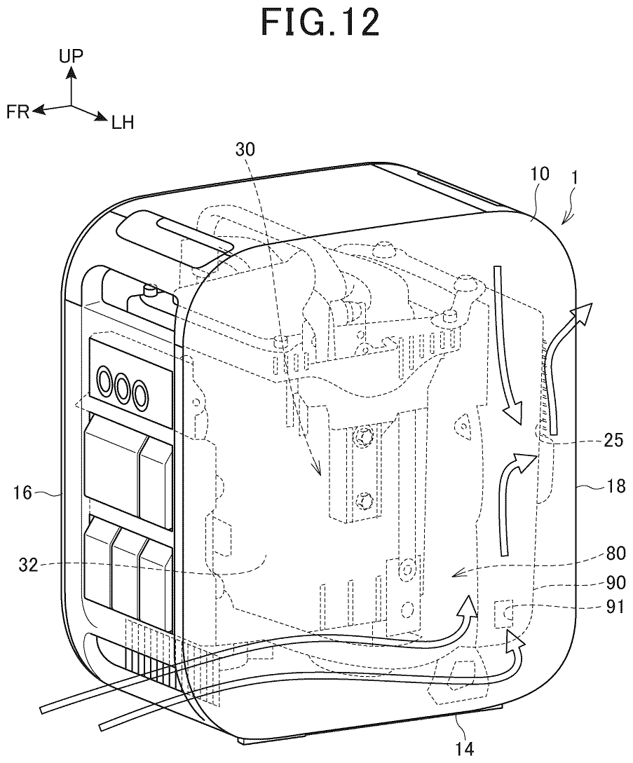

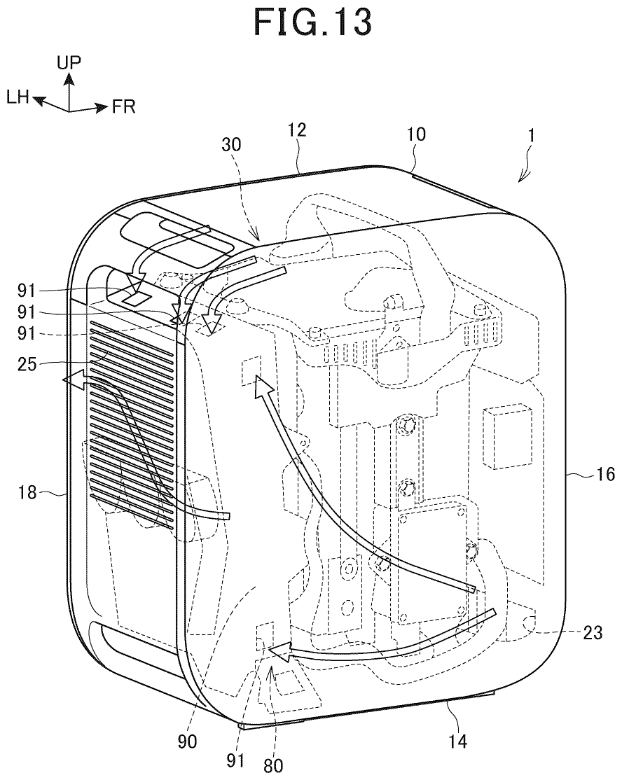

FIG. 12 and FIG. 13 are each a schematic view showing a flow of cooling air in the accommodation device 1. FIG. 12 is a perspective view in which the accommodation device 1 is seen from a front surface side, and FIG. 13 is a perspective view in which the accommodation device 1 is seen from a rear surface side. In FIG. 12 and FIG. 13, air flowing inside the housing 10 by the air blowers 92 is shown by arrows. When the battery 100 is accommodated in the accommodation device 1, and the accommodation device 1 starts driving from the battery 100, each of the air blowers 92 is driven. As shown in FIG. 13 and FIG. 12, according to this, air is taken into the inside from the outside of the housing 10, via the front surface air intake slot 23. The taken-in air passes through below the battery case 32, and the taken-in air passes through the left and right sides.

Afterwards, a part of the air passes through between the inverter 82 and the side wall 48 of the battery case 32 positioned on a rear side of the housing 10.

According to this, a part of the air cools the substrate 84, the electrical components 86, and the battery 100, the electrical components 86 being mounted on a flat surface of the substrate 84 with respect to the battery case 32 of the inverter 82. In this case, the side wall 48 functions as an air guide member for restricting air so that the air flows along the electrical components 86 and the substrate 84.

This air rises to an upper end of the substrate 84, and thereafter the air is sucked from the shroud air intake slots 91 to the inside of the inverter unit 80, the shroud air intake slots 91 being provided on an upper end side of the shroud 90. On the other hand, a part of the air does not pass through between the inverter 82 and the side wall 48, and this part of the air is sucked from each of the shroud air intake slots 91 to the inside of the inverter unit 80, each of the shroud air intake slots 91 being provided on each of a lower end and side edge of the shroud 90.

As stated above, each of the shroud air intake slots 91 positioned on a lower end side of the shroud 90 is disposed at a position not overlapping the battery case 32, in a view from a front side of the housing 10. Accordingly, air sucked into the shroud air intake slots 91 being inhibited by the battery case 32 is suppressed.

In addition, each of the shroud air intake slots 91 positioned on a lower end side of the shroud 90 is positioned on an opposite side to the insertion/removal slot 31 of the battery case 32, in an up-down direction of the housing 10. Accordingly, air sucked into the shroud air intake slots 91 being inhibited by the accommodation mechanism 30, or air sucked into the shroud air intake slots 91 being inhibited by a connection structure between the upper surface panel 12 and the battery case 32, is suppressed.

Air sucked into the inverter unit 80 flows across the entire surface of the substrate 84, while the air sucked into the inverter unit 80 cools the substrate 84 and the electrical components 86. This air is taken into each of the air blowers 92, thereafter this air is discharge to the outside of the inverter unit 80, and this air is discharged to the outside of the housing 10 from the rear surface discharge slot 25. According to this, it is possible for the accommodation device 1 to more efficiently cool heat generating members such as the inverter 82 and the battery 100.

As shown in FIG. 6, each of the pair of handles 28, the hand hooking portion 14b, and the hand hooking portion 14c are disposed on an upper end or a lower end of the inverter unit 80, or each of the pair of handles 28, the hand hooking portion 14b, and the hand hooking portion 14c are disposed on an upper end or a lower end of each of the user interface unit 22 and the terminal unit 24. Namely, each of the pair of handles 28, the hand hooking portion 14b, and the hand hooking portion 14c is disposed at a position that avoids a range where the battery 100 is inserted and removed to/from the accommodation mechanism 30. According to this, in the accommodation device 1, the portability of the accommodation device 1 can be improved, while enabling attachment and detachment of the battery 100.

In the accommodation device 1 in which the battery 100 is stored, the battery 100 becomes the heaviest member. In the accommodation device 1, each of the pair of handles 28, the hand hooking portion 14b, and the hand hooking portion 14c is disposed at each of the corner portions of the housing 10, in a view from a left-right direction of the housing 10. Accordingly, in the case where a user holds any two of the pair of handles 28, the hand hooking portion 14b, and the hand hooking portion 14c to be transported, the battery 100 is positioned between the portions that the user holds. According to this, in the accommodation device 1, it is possible to more surely transport the accommodation device 1 while supporting the accommodation device 1.

As stated above, the hand hooking portion 14b and the hand hooking portion 14c are integrally provided with the lower surface panel 14. This lower surface panel 14 is a member coupled to the battery case 32 for holding the battery 100. According to this, in the case where a user holds at least either the hand hooking portion 14b or the hand hooking portion 14c, the battery 100 is secured via the lower surface panel 14 and the battery case 32. Accordingly, in the case where a user holds at least either the hand hooking portion 14b or the hand hooking portion 14c, in the accommodation device 1, it is possible to more surely transport the accommodation device 1 while supporting the accommodation device 1.

The above-stated embodiment exemplifies one aspect of the present invention, and the above-stated embodiment can be arbitrarily modified and applied in a range that does not deviate from the content of the present invention.

For example, while the accommodation device 1 of the present embodiment is an electrical power supply device for supplying electrical power to outside of the device, by making the battery 100 stored inside of the housing 10 a power source, the present invention is not limited to this, and the accommodation device 1 may be an electrical power consuming device including an electrical power consuming portion integrally formed with this device, such as a light source or voice output device.

Moreover, for example, in the above-stated embodiment, while the case frame body 50 is formed separate from the battery case 32, the present invention is not limited to this, and the case frame body 50 may be integrally formed with the battery case 32.

Moreover, for example, the accommodation device 1 may include a seal material for sealing a gap between the accommodation mechanism 30 and the battery 100 to be liquid tight, the battery 100 being accommodated in the accommodation mechanism 30, and the accommodation device 1 may include a sealing structure formed by this seal material. In this case, the accommodation device 1 may have the cover body 20 omitted.

In the above-stated embodiment, while the battery 100 is formed in a rotationally asymmetrical shape with the virtual line V as an axis of rotation, the present invention is not limited to this, and the battery 100 may be formed in a rotationally symmetrical shape such as a columnar shape. In addition, the battery terminal 108 may be formed so as to have a position and shape in which the battery 100 becomes a rotationally symmetrical shape.

In the above-stated embodiment, while the accommodation device 1 and the accommodation mechanism 30 accommodate the battery 100 including a battery cell inside as an electrical storage device, the present invention is not limited to this, and the accommodation device 1 and the accommodation mechanism 30 may accommodate another electrical storage device such as a capacitor.

In the above-stated embodiment, the accommodation device 1 accommodates the battery 100, as a portable energy accumulator, the battery 100 storing electrical power. However, the present invention is not limited to this, and the accommodation device 1 may attachably/detachably accommodate, for example, a fuel cell using hydrogen or the like. Moreover, for example, the accommodation device 1 may include an accumulator of fuel used for power generation, such as a hydrogen container for storing hydrogen used in a fuel cell, or a so-called portable hydrogen tank.

Moreover, for example, the accommodation device 1 may include a combustion engine such as an engine, and the accommodation device 1 may attachably/detachably accommodate a container for storing liquid fuel such as gasoline combusted in the combustion engine, or the accommodation device 1 may attachably/detachably accommodate a container for storing gaseous fuel such as hydrogen. In this way, the accommodation device 1 is not limited to a portable energy accumulator, and the accommodation device 1 may attachably/detachably accommodate a container for storing an energy source such as fuel. In this case, the accommodation device 1 includes a mechanism for storing electrical power from an energy source such as hydrogen.

In the above-stated embodiment, while the accommodation device 1 includes a power supply function and a power charging function, the present invention is not limited to this, and the accommodation device 1 may include only a power supply function, or the accommodation device 1 may include only a power charging function.

The directions such as a horizontal direction and a vertical direction, and the various types of shapes, in the above-stated embodiment, include a so-called equivalent range, which is a range that accomplishes the same working effect as these directions and shapes, unless otherwise noted.

### CONFIGURATIONS SUPPORTED BY THE EMBODIMENTS

The above-stated embodiment supports the following configurations.
(Configuration 1) An accommodation device including a housing including six substantially quadrangular surfaces facing mutually different directions, the housing being provided in a substantially polyhedral shape, and an accommodation unit provided inside the housing, the accommodation unit accommodating a portable energy accumulator to enable the portable energy accumulator to be inserted and removed, in which an opening is provided on the accommodation unit, the opening enabling the portable energy accumulator to be inserted and removed, the opening is provided at a position corresponding to a first surface being one of the six surfaces, the first surface has a first side and a second side, the first side and the second side being two sides parallel to one another, and a first handle is provided at a position corresponding to the first side on the housing, the first handle being for a user to hold, and a second handle is provided at a position corresponding to the second side on the housing, the second handle being for the user to hold. According to this configuration, the accommodation device can be transported and the accommodation device can be held, while enabling the portable energy accumulator to be inserted and removed to/from the accommodation unit. Accordingly, in the accommodation device, a user can transport the accommodation device while more surely supporting the accommodation device.
(Configuration 2) The accommodation device described in Configuration 1, further including an energy conversion portion enabling energy transmission with the portable energy accumulator accommodated in the accommodation unit, in which the energy conversion portion is provided at a position side by side with the accommodation unit inside the housing, the position being in a direction intersecting the first side and the second side. According to this configuration, the energy conversion portion can be provided, while enabling the portable energy accumulator to be inserted and removed to/from an opening accommodation unit that enables the portable energy accumulator to be inserted and removed. Accordingly, in the accommodation device, energy transmission with the portable energy accumulator can be performed, while enabling the portable energy accumulator to be inserted and removed to/from the accommodation unit.
(Configuration 3) The accommodation device described in Configuration 2, in which at least a part of the energy conversion portion is provided at a position overlapping at least either the first handle or the second handle in a direction view orthogonal to the first surface. According to this configuration, the accommodation device can dispose the energy conversion portion, by having the accommodation device efficiently utilize a space of a position overlapping a handle in a direction view orthogonal to the first surface. Accordingly, the accommodation device can suppress an increase in size of the accommodation device. In addition, in the accommodation device, the accommodation device can be transported and the accommodation device can be held, while enabling the portable energy accumulator to be inserted and removed to/from the accommodation unit. Accordingly, in the accommodation device, a user can transport the accommodation device while surely supporting the accommodation device. In addition, in the accommodation device, the user can more surely support the energy conversion portion stored in the accommodation device.
(Configuration 4) The accommodation device described in Configuration 2 or 3, further including a connection portion provided to enable energy transmission with the energy conversion portion, an external device being connected to the connection portion, in which the connection portion is provided at a position corresponding to a second surface from among the six surfaces, the second surface being a surface intersecting the first surface. According to this configuration, the connection portion can be provided at a position that avoids an opening where the portable energy accumulator can be inserted and removed. Accordingly, in the accommodation device, the accommodation device and another device can be connected one another, while enabling the portable energy accumulator to be inserted and removed to/from the accommodation unit.
(Configuration 5) The accommodation device described in Configuration 4, in which the connection portion is provided on an opposite side of the energy conversion portion across the accommodation unit in a direction intersecting the second surface. According to this configuration, each of the energy conversion portion and the connection portion can be provided at a position that avoids an opening where the portable energy accumulator can be inserted and removed. Accordingly, in the accommodation device, energy transmission between the portable energy accumulator and another device can be performed, while enabling the portable energy accumulator to be inserted and removed to/from the accommodation unit.
(Configuration 6) The accommodation device described in Configuration 4 or 5, in which at least a part of the connection portion is provided at a position overlapping at least either the first handle or the second handle in a direction view orthogonal to the first surface. According to this configuration, the accommodation device can be transported and the accommodation device can be held, while enabling the portable energy accumulator to be inserted and removed to/from the accommodation unit. Accordingly, in the accommodation device, a user can transport the accommodation device while more surely supporting the accommodation device. In addition, in the accommodation device, the user can more surely support the connection portion.
(Configuration 7) The accommodation device described in any one of Configurations 4 to 6, further including an interface portion on which a display portion and/or an operation portion are/is provided, the display portion being for displaying information to the user, the operation portion being operated by the user, in which the interface portion is provided at a position corresponding to the second surface. According to this configuration, the interface portion can be provided at a position that avoids an opening where the portable energy accumulator can be inserted and removed. Accordingly, in the accommodation device, a user can operate the accommodation device, while enabling the portable energy accumulator to be inserted and removed to/from the accommodation unit.
(Configuration 8) The accommodation device described in Configuration 7, in which at least a part of the interface portion is provided at a position overlapping at least either the first handle or the second handle in a direction view orthogonal to the first surface. According to this configuration, the accommodation device can be transported and the accommodation device can be held, while enabling the portable energy accumulator to be inserted and removed to/from the accommodation unit. Accordingly, in the accommodation device, a user can transport the accommodation device while more surely supporting the accommodation device. In addition, in the accommodation device, the user can more surely support the interface portion.
(Configuration 9) The accommodation device described in Configuration 7 or 8, in which at a time when the housing is loaded in a first posture being a posture in which the first surface is toward a vertical direction upside, the interface portion is positioned more on a vertical direction upside than the connection portion. According to this configuration, the interface portion is disposed at a position where an operation by a user is easy. Accordingly, in the accommodation device, it becomes easy for the user to operate.
(Configuration 10) The accommodation device described in any one of Configurations 1 to 9, in which the housing has three surfaces from among the six surfaces, the three surfaces being surfaces parallel to the first surface, the third surface includes a third side parallel to the first side, and a third handle is provided at a position corresponding to the third side on the housing, the third handle being for the user to hold. According to this configuration, a plurality of handles can be provided, while enabling the portable energy accumulator to be inserted and removed to/from the accommodation unit. Accordingly, in the accommodation device, a user can transport the accommodation device while more surely supporting the accommodation device.
(Configuration 11) The accommodation device described in Configuration 10, in which the third surface includes a fourth side parallel to the third side, and a fourth handle is provided at a position corresponding to the fourth side on the housing, the fourth handle being for the user to hold. According to this configuration, a plurality of handles can be provided, while enabling the portable energy accumulator to be inserted and removed to/from the accommodation unit. Accordingly, in the accommodation device, a user can transport the accommodation device while more surely supporting the accommodation device.
(Configuration 12) The accommodation device described in any one of Configurations 1 to 11, in which the portable energy accumulator is a power accumulator for storing electrical power, the power accumulator has a switching control portion for switching between an activation state and a deactivation state, the activation state being capable of outputting electrical power to the outside or the activation state being capable of inputting electrical power of the outside, and the deactivation state being not capable of outputting electrical power to the outside or the deactivation state being not capable of inputting electrical power of the outside, another power accumulator is provided inside the housing, the other power accumulator capable of electrical transmission with the switching control portion, and the other power accumulator is provided at a position side by side with the accommodation unit in a direction in which the first side and the second side extend. According to this configuration, another power accumulator can be provided, while enabling the portable energy accumulator to be inserted and removed to/from the accommodation unit. Accordingly, in the accommodation device, energy transmission with the portable energy accumulator can be performed, while enabling the portable energy accumulator to be inserted and removed to/from the accommodation unit.
(Configuration 13) The accommodation device described in any one of Configurations 1 to 12, in which the portable energy accumulator is a power accumulator having a first electrical terminal, the power accumulator for storing electrical power, the portable energy accumulator includes a power transmission mechanism for transmitting power to move a second electrical terminal connected to the first electrical terminal and/or the portable energy accumulator includes a power transmission mechanism for transmitting power to move a pressing portion pressed against the power accumulator accommodated in the accommodation unit, the power transmission mechanism is provided to enable movement between a first position and a second position, the first position becoming a state where the second electrical terminal is connected to the first electrical terminal and/or the first position becoming a state where the pressing portion is pressed against the power accumulator, and the second position becoming a state where the second electrical terminal is not connected to the first electrical terminal and/or the second position becoming a state where the pressing portion is not pressed against the power accumulator, and at least a part of the electrical power transmission mechanism is provided at a position overlapping the opening in a direction view orthogonal to the first surface at a time of the first position. According to this configuration, the accommodation device enables a user to operate the power transmission mechanism via an opening.
(Configuration 14) The accommodation device described in Configuration 13, further including a covering portion openably and closably provided to cover at least a part of the opening, in which the covering portion is provided at a position corresponding to the first surface. According to this configuration, the accommodation device can openably and closably cover an opening, at a position that becomes an upper surface in an upright posture.
(Configuration 15) The accommodation device described in Configuration 14, in which the covering portion has an expanded portion for expanding toward the opening from a surface of the opening side in a closed state. According to this configuration, in the accommodation device, driving of the power transmission mechanism can be restricted, by the expanded portion.
(Configuration 16) The accommodation device described in Configuration 15, in which at least a part of the power transmission mechanism is provided at a position side by side with the expanded portion in a direction intersecting the first side and the second side at a time when the power transmission mechanism is at the first position. According to this configuration, in the accommodation device, driving of the power transmission mechanism can be restricted, by the expanded portion.
(Configuration 17) The accommodation device described in Configuration 16, in which at least a part of the power transmission mechanism is provided at a position overlapping a movement trajectory of the expanded portion at a time when the power transmission mechanism is at the second position and at a time when the covering portion is opened and closed. According to this configuration, in the accommodation device, driving of the power transmission mechanism can be restricted, by the expanded portion.
(Configuration 18) The accommodation device described in any one of Configurations 15 to 17, in which the expanded portion is provided to have a space inside. According to this configuration, in the accommodation device, a predetermined item can be accommodated inside the expanded portion.
(Configuration 19) The accommodation device described in Configuration 18, in which the expanded portion has an opening and closing portion provided to open and close the space. According to this configuration, the accommodation device can accommodate a predetermined item inside the expanded portion, and the accommodation device can block the expanded portion to hold the item stored inside.
(Configuration 20) The accommodation device described in Configuration 19, in which the opening and closing portion is provided with the space being opened toward a vertical direction upside at a time when the opening and closing portion is opened in a state where the covering portion is opened. According to this configuration, the accommodation device can easily perform an operation of the expanded portion, in a state where an opening is opened.

### REFERENCE SIGNS LIST

1 accommodation device
10 housing
12 upper surface panel (first surface)
13 upper surface opening
14 lower surface panel
14b, 14c hand hooking portion (third handle, fourth handle)
16 front surface panel (second surface)
18 rear surface panel
19 side surface panel
24 terminal unit (connection portion)
28 handle (first handle, second handle)
30 accommodation mechanism
31 insertion/removal slot
32 battery case
80 inverter unit
82 inverter (energy conversion portion)
90 shroud
100 battery (portable energy accumulator)
120 communication unit
130 processor (switching control portion)

1. An accommodation device, comprising:
a housing comprising six substantially quadrangular surfaces facing mutually different directions, the housing being provided in a substantially polyhedral shape; and
an accommodation unit provided inside the housing, the accommodation unit accommodating a portable energy accumulator to enable the portable energy accumulator to be inserted and removed, wherein
an opening is provided on the accommodation unit, the opening enabling the portable energy accumulator to be inserted and removed,
the opening is provided at a position corresponding to a first surface being one of the six surfaces,
the first surface has a first side and a second side, the first side and the second side being two sides parallel to one another, and
a first handle is provided at a position corresponding to the first side on the housing, the first handle being for a user to hold, and a second handle is provided at a position corresponding to the second side on the housing, the second handle being for the user to hold.

2. The accommodation device according to claim 1, further comprising:
an energy conversion portion enabling energy transmission with the portable energy accumulator accommodated in the accommodation unit, wherein
the energy conversion portion is provided at a position side by side with the accommodation unit inside the housing, the position being in a direction intersecting the first side and the second side.

3. The accommodation device according to claim 2, wherein
at least a part of the energy conversion portion is provided at a position overlapping at least either the first handle or the second handle in a direction view orthogonal to the first surface.

4. The accommodation device according to claim 2, further comprising:
a connection portion provided to enable energy transmission with the energy conversion portion, an external device being connected to the connection portion, wherein
the connection portion is provided at a position corresponding to a second surface from among the six surfaces, the second surface being a surface intersecting the first surface.

5. The accommodation device according to claim 4, wherein
the connection portion is provided on an opposite side of the energy conversion portion across the accommodation unit in a direction intersecting the second surface.

6. The accommodation device according to claim 4, wherein
at least a part of the connection portion is provided at a position overlapping at least either the first handle or the second handle in a direction view orthogonal to the first surface.

7. The accommodation device according to claim 4, further comprising:
an interface portion on which a display portion and/or an operation portion are/is provided, the display portion being for displaying information to the user, the operation portion being operated by the user, wherein
the interface portion is provided at a position corresponding to the second surface.

8. The accommodation device according to claim 7, wherein
at least a part of the interface portion is provided at a position overlapping at least either the first handle or the second handle in a direction view orthogonal to the first surface.

9. The accommodation device according to claim 7, wherein
at a time when the housing is loaded in a first posture being a posture in which the first surface is toward a vertical direction upside,
the interface portion is positioned more on a vertical direction upside than the connection portion.

10. The accommodation device according to claim 1, wherein
the housing has a third surface from among the six surfaces, the third surface being a surface parallel to the first surface,
the third surface comprises a third side parallel to the first side, and
a third handle is provided at a position corresponding to the third side on the housing, the third handle being for the user to hold.

11. The accommodation device according claim 10, wherein
the third surface comprises a fourth side parallel to the third side, and
a fourth handle is provided at a position corresponding to the fourth side on the housing, the fourth handle being for the user to hold.

12. The accommodation device according to claim 1, wherein
the portable energy accumulator is a power accumulator for storing electrical power,
the power accumulator has a switching control portion for switching between an activation state and a deactivation state,
the activation state being capable of outputting electrical power to the outside or the activation state being capable of inputting electrical power of the outside, and the deactivation state being not capable of outputting electrical power to the outside or the deactivation state being not capable of inputting electrical power of the outside,
another power accumulator is provided inside the housing, the other power accumulator capable of electrical transmission with the switching control portion, and
the other power accumulator is provided at a position side by side with the accommodation unit in a direction in which the first side and the second side extend.

13. The accommodation device according to claim 1, wherein
the portable energy accumulator is a power accumulator having a first electrical terminal, the power accumulator for storing electrical power,
the portable energy accumulator comprises a power transmission mechanism for transmitting power to move a second electrical terminal connected to the first electrical terminal and/or the portable energy accumulator comprises a power transmission mechanism for transmitting power to move a pressing portion pressed against the power accumulator accommodated in the accommodation unit,
the power transmission mechanism is provided to enable movement between a first position and a second position,
the first position becoming a state where the second electrical terminal is connected to the first electrical terminal and/or the first position becoming a state where the pressing portion is pressed against the power accumulator, and the second position becoming a state where the second electrical terminal is not connected to the first electrical terminal and/or the second position becoming a state where the pressing portion is not pressed against the power accumulator, and
at least a part of the electrical power transmission mechanism is provided at a position overlapping the opening in a direction view orthogonal to the first surface at a time of the first position.

14. The accommodation device according claim 13, further comprising:
a covering portion openably and closably provided to cover at least a part of the opening, wherein
the covering portion is provided at a position corresponding to the first surface.

15. The accommodation device according claim 14, wherein
the covering portion has an expanded portion for expanding toward the opening from a surface of the opening side in a closed state.

16. The accommodation device according claim 15, wherein
at least a part of the power transmission mechanism is provided at a position side by side with the expanded portion in a direction intersecting the first side and the second side at a time when the power transmission mechanism is at the first position.

17. The accommodation device according claim 16, wherein
at least a part of the power transmission mechanism is provided at a position overlapping a movement trajectory of the expanded portion at a time when the power transmission mechanism is at the second position and at a time when the covering portion is opened and closed.

18. The accommodation device according claim 15, wherein
the expanded portion is provided to have a space inside.

19. The accommodation device according claim 18, wherein
the expanded portion has an opening and closing portion provided to open and close the space.

20. The accommodation device according claim 19, wherein
the opening and closing portion is provided with the space being opened toward a vertical direction upside at a time when the opening and closing portion is opened in a state where the covering portion is opened.
